(19) United States
(12) Patent Application Publication
(10) Pub. No.: US 2010/0060289 A1
(43) Pub. Date: Mar. 11, 2010

(54) System for Electrical Apparatus Testing

(75) Inventors: Ernesto Wiedenbrug, Fort Collins, CO (US); Sang Bin Lee, Seoul (KR)

Correspondence Address: SANTANGELO LAW OFFICES, P.C., 125 SOUTH HOWES, THIRD FLOOR, FORT COLLINS, CO, 80521, US

(73) Assignee: SKF USA, Inc., Norristown, PA (US)

(21) Appl. No.: 12/205,816

(22) Filed: Sep. 5, 2008

(51) Int. Cl. G01R 31/00

(52) U.S. Cl. 324/511

(57) ABSTRACT

An easily implemented method of diagnosing both supply path, upstream, and load path, downstream, anomalies such as impedance events in machine or motor circuitry is accomplished by analyzing the across-the-line startup current and voltage time waveforms. No line of sight limitations exist and high accuracy exists. The techniques can be automated estimating poor contact resistance based on the voltage and current variation under a load change condition perhaps such as startup and/or shutdown of the load. Both, upstream and downstream problems from the point of voltage measurement can be monitored analyzing a load change condition. Additionally, downstream problems can be identified by using negative sequence current under steady state operation of the load.

### BACKGROUND

The present invention relates to methods and devices to test electric machine circuitry. Specifically it relates to system, through which upstream and downstream circuitry can be tested to detect incipient and existing faults.

Electric machines, such as electric motors or the like play a critical role in our society. They often provide operations which many times cannot be interrupted. Continued, uninterrupted operation is often critical to the devices for which they are a component. Oftentimes, they cannot be permitted to fail. Unfortunately, their operation can at times be attended by corroded contacts and weakened connections.

High-resistance(R) connections can occur due to poor contact at the joint of any device connected between the source and load in an electrical distribution system of an industrial facility as shown in FIG. 1. As shown thermographically in FIG. 3, corroded contacts can even be a source of danger. The location of poor contacts may also be classified as upstream, in the supply path, or downstream, in the load path, depending on whether the problem is located on the source side or load side from the point of voltage or other measurement, as shown in FIG. 1. These problems, which are common in industry, are usually initiated due to a combination of poor workmanship (mainly under-tightening of connectors), loose connections, or corrosion/oxidation/contamination/damage in the contact surface. Once a high-R contact is created, repeated thermal cycling and vibration may deteriorate the contact quality at an elevated rate and may increase the contact resistance. The connector components may expand and contract with thermal cycling due to variations in the current level. This, combined with vibration, can loosen the connection which may increase the contact resistance and local temperature. Heating at the contact can accelerate oxidation at the surface and can increase the resistance and temperature further.

If the contact resistance increases to an unsafe level, this can result in localized overheating as shown in FIG. 3, supply voltage unbalance, and/or sparking. Local thermal overloading at the contact may be one of the leading root causes of failure in electrical distribution systems. This can cause open circuit failures (melting of conductor/contact) or short circuit failures (insulation damage) in the electric circuit. Supply voltage unbalance can cause negative sequence current flow in the load, which can result in thermal overheating and vibration of machine or motor loads. This can accelerate the degradation of machine or motor insulation, which is often one of the main root causes of failure.

High-R connections can also reduce the system efficiency and can increase the safety risks in addition to decreasing the distribution circuit and machine or motor reliability, as explained above. The efficiency of the electrical distribution system and load can suffer when high-R contacts are present. According to one study, 36% of the electrical distribution system problems that result in decreased efficiency are due to poor connections. A distribution of some fault statistics is shown in FIG. 4. As mentioned, the efficiency of machine or motor loads can be decreased when the input supply voltage is unbalanced, since negative sequence current can cause additional winding losses and can induce negative torque that decreases the output. It is known that overheating and sparking at the high-R contact can initiate electric fires, and that a significant portion of building fires are caused by poor contacts. The statistical data show that is important to monitor and correct high-R connections for reliable, efficient, and safe operation of the industrial facility.

Analyzing either or both upstream and downstream resistance of a three-phase system can identify connection problems. Unfortunately, upstream connection problems are particularly difficult to assess because the upstream circuitry can usually only be viewed in its entirety, that is, from its very source to the point of measurement. Unlike the downstream path which can be limited by the measurement point to only the machine or motor and perhaps an associated control center or Motor Control Center (MCC), the upstream circuitry is almost a complete unknown and is almost completely unpredictable.

Several main existing technologies used today for P/PM (predictive/preventive maintenance) activities in electrical machine or motor circuitry include: resistive balance measurements, voltage drop testing, and thermographic techniques such as infrared imaging (IR). Resistive balance measurements are often used to evaluate the condition of downstream equipment. This technology's disadvantages are that the testing needs to be performed offline and it needs to be connected directly to the voltage buss. The most expensive machine or motors in industry, however, tend to be medium or high voltage. To be able to connect to the conductors and perform a resistive balance on these machines or motors, one typically must pull the breaker—which is disruption to the normal flow of operations in the plant or equipment. A further disadvantage to this method is that it is usually only capable of finding high resistance connections downstream from where the equipment is connected. The resistive imbalance test is therefore usually an off-line test that often measures the percent difference between the phase-to-phase resistances of the three phases under DC excitation. Although it is very effective for detecting high-R problems, its limitations of being performed off-line and usually only being able to identify problems downstream from where the test is performed remain as significant drawbacks.

Another existing test technique is the voltage drop test. The voltage drop test is an on-line test that can be a simple, low cost voltmeter test. It usually compares the voltage drop in the distribution circuit between phases to identify high-R connections. This usually requires that the Motor Control Center (MCC) be opened and this can cause safety hazards. As an online test, the intrusion of a voltage measurement can create risks.

The thermographic testing technique is usually based on an infrared (IR) technique. To use IR to find high resistance connection problems one must have good line of sight to the location of the problem. This also usually means that the Motor Control Center (MCC) either needs to be opened—causing obvious safety arc flash hazards—or suitable IR windows need to be installed in all locations with a potential of failure. One example of IR imaging is shown in FIG. 3. This illustrates an IR view of a loose connection on a three phase buss bar. Infrared (IR) thermography usually is employed to monitor the temperature distribution in the power circuit using a thermal imaging camera to identify hot spots, as shown in FIG. 3. IR thermography can be safer, faster, and more accurate compared to the voltage drop test for finding high-R contacts, but it is attended by the drawbacks of requiring good line of sight to the problem and expensive equipment or service. These on-line tests can only be performed when the machine is in use, and the results depend on the load current making it difficult to assess the severity of the fault. All the tests available for monitoring high-R connections are inconvenient since they are either offline or walk-around type tests and do not provide continuous monitoring capability.

A more recently proposed technique is a neural network test technique. The neural network-based method involves calculating the negative sequence current due to high-R connections. The validity of the method has been shown experimentally; however, the method requires intensive computation and training of the neural network.

Another technique for detecting high-R connections based on negative sequence current or zero sequence voltage has been proposed. Like the neural network technique, this newer technique appears limited by its symmetrical component based nature. Thus, it appears that it can only detect high-R problems located downstream from the point of voltage measurement.

From the above, it can be seen that it is desirable to have an automated monitoring technique that is capable of monitoring and quantifying both upstream and downstream high-R contact problems. It is also desirable to have a technique that does not require significant additional equipment or measurements. It is also desirable to have a technique that can be operated continuously while the system is in normal operation and that has the precision and accuracy to identify incipient faults or anomalies, that is, those that provide an indication even before they cause a problem so that maintenance can be scheduled at a convenient time. Unfortunately none of the above techniques fulfill these criteria.

### SUMMARY OF THE INVENTION

The present invention provides a way to monitor for and quantitatively identify incipient high-R contacts in a way that is more convenient than most existing techniques. It provides a fundamentally new technique that overcomes many of the problems of existing methods. It presents a fully automated technique that can monitor for high-R connections located both upstream and downstream during normal load operation. It can also provide this ability based on the existing voltage and current measurements so little additional equipment or capabilities are required.

In a variety of embodiments the present invention presents a new understanding from which even upstream faults can not only be detected, but can be quantified and located with a high degree of accuracy. Embodiments of the invention can provide techniques that quantify even incipient faults by using unique conditions that usually already exist in normal operation of the machine or motor circuitry. These techniques can be fully automated to operate substantially continuously for multiphase and even single phase machine or motor topologies. They can even be augmented to detect downstream faults in a manner that avoids many of the dangers and difficulties of existing techniques.

Accordingly, it is an objective of embodiments of the present invention to provide techniques that overcome the limitations of the most existing test methods. An objective is to provide a system that can be implemented with what is often an existing measurement access so that new risks or expenses are either not created or are minimized. It is also an objective to provide test capabilities that can determine potential faults with a high degree of accuracy without intrusive test activities.

Naturally, other objectives are presented throughout the specification and claims, and the above list is not to be construed as limiting.

### BRIEF DESCRIPTION OF THE DRAWINGS

FIG. 1 is a block diagram of an electrical machine distribution system according to the present invention.

FIG. 2 is a typical single line diagram of the electrical distribution system of an industrial facility with upstream and downstream defined.

FIG. 3 is overheating in terminal block due to a high-R connection in the electrical distribution system of an industrial plant.

FIG. 4 is a summary of problems resulting in increased electrical losses in electrical distribution systems.

FIG. 5 is a typical circuit of a three phase electrical distribution system with an equivalent circuit with a high-R connection in phase A located upstream, R_{HR.up}, and downstream R_{HRdown}, from the point of measurement or sensing.

FIG. 6 is a three-phase connection circuit for an induction machine.

FIG. 7 is a single-phase circuit.

FIG. 8 is a sample of a startup behavior of a three phase induction motor.

FIG. 9 is (a) positive sequence, and (b) negative sequence steady state equivalent circuits of a three phase load with high-R connection located downstream.

FIG. 10 is a typical waveform of the source voltage and current magnitude and phase angle under startup and shutdown of the load.

FIG. 11 is a phasor diagram representation of the change in V_{ag} measurement with high-R connection under (a) startup and (b) shutdown of load.

FIG. 12 is (a) complex plane representation of upstream impedance estimates and (b) pattern of the upstream impedance estimated from phase AB, BC, CA voltage measurements for high-R faults located in phase A, B, C.

FIG. 13 is a laboratory experimental setup for testing the proposed upstream and downstream high-R connection monitoring techniques.

FIG. 14 shows experimental measurements of magnitude & phase angel of ν_{a′g}& iₐₛ for estimation of R_{HR,up} under startup(no load; R_{HR,up}=0.4Ω).

FIG. 15 shows experimental measurements of magnitude & phase angel of ν_{a′g}& iₐₛ for estimation of R_{HR,up} under shutdown (full load; R_{HR,up}=0.4Ω).

FIG. 16 shows experimental results of R_{HR,up} estimates obtained at startup and shutdown conditions (no load, half load, and full load conditions) for R_{HR,up}=0, 0.05, 0.1, 0.2, 0.4Ω with line-neutral and line-line voltage measurements.

FIG. 17 shows complex plane representations of upstream impedance from line-line voltage measurements obtained under startup conditions for R_{HR,up}=0, 0.05, 0.1, 0.2, 0.4Ω.

FIG. 18 is a table of experimental results of R_{HR,up} estimates obtained at startup and shutdown conditions (no load, half load, and full load conditions) for R_{HR,down}=0, 0.05, 0. 1, 0.2, 0.4Ω (line neutral voltage measurement).

FIG. 19 is a table of experimental results of R_{HR,up} estimates obtained at startup and shutdown conditions (no load, half load, and full load conditions) for R_{HR,down}=0, 0.05, 0.1, 0.2, 0.4Ω (line-line voltage measurement).

FIG. 20 shows experimental measurements of magnitude & phase angle of νₛₙ, iₛₙ, and i_{sn,HR} for estimation of R_{HR,down} (R_{HR,down}=0, 0.05, 0.1, 0.2, 0.4Ω).

FIG. 21 shows experimental results of R_{HR,down} estimates under rated load (R_{HR,down}=0, 0.05, 0.1, 0.2, 0.4Ω).

FIG. 22 shows experimental results of R_{HR,up} estimates obtained at no load startup and full load shutdown conditions; R_{HR,down} estimates and maximum temperature measurements obtained under half load conditions for loose 1, loose 2, and loose 3 high-R contact conditions.

FIG. 23 is a table of experimental results of R_{HR,up} estimates obtained at no load startup and full load shutdown conditions; R_{HR,down} estimates and maximum temperature measurements obtained under half load conditions for loose 1, loose 2, and loose 3 high-R contact conditions.

FIG. 24 shows calculated resistance divided by motor resistance as a function of actual resistance divided by motor resistance in percent for 0% voltage unbalance.

FIG. 25 is a data capture from a test showing time varying waveforms for voltage and current.

FIG. 26 shows the simulated (a) magnitude and (b) phase angle effects of the three phase stator current during the startup transient when there is a high-resistance contact in one phase (0.05 Ohm).

FIG. 27 shows the simulated (a) real and (b) imaginary components of the three phase impedance during the startup transient when there is a high-resistance contact in one phase (0.05 Ohm).

FIG. 28 shows the simulated (a) magnitude and (b) phase angle of the positive sequence current during the startup transient when there is a high-resistance contact in one phase (0.05 Ohm).

FIG. 29 shows the simulated (a) magnitude and (b) phase angle of the positive sequence current during the startup transient when there is a high-resistance contact in one phase (0.05 Ohm).

FIG. 30 shows the estimate of the contact resistance during the startup transient when there is a high-resistance contact in one phase (0.050 hm).

FIG. 31 shows the estimate of the contact resistance during the startup transient when there is a high-resistance contact in one phase and when there is a 0.5% voltage unbalance (contact resistance estimate is not influenced significantly during the startup transient).

FIGS. 31 and 32 shows the estimate of the contact resistance during the startup transient when there is a high-resistance contact in one phase and when inherent negative sequence current is 0.5% of rated current (contact resistance estimate is not influenced significantly during the startup transient).

### DESCRIPTION OF THE PREFERRED EMBODIMENTS

The present invention includes a variety of aspects, which may be combined in different ways. The following descriptions are provided to list actions and elements and to describe some of the embodiments of the present invention. These elements are listed with initial embodiments, however it should be understood that they may be combined in any manner and in any number to create additional embodiments. The variously described examples and preferred embodiments should not be construed to limit the present invention to only the explicitly described systems, techniques, and applications. Further, this description should be understood to support and encompass descriptions and claims of all the various embodiments, systems, techniques, methods, devices, and applications with any number of the disclosed elements, with each element alone, and also with any and all various permutations and combinations of all elements in this or any subsequent application.

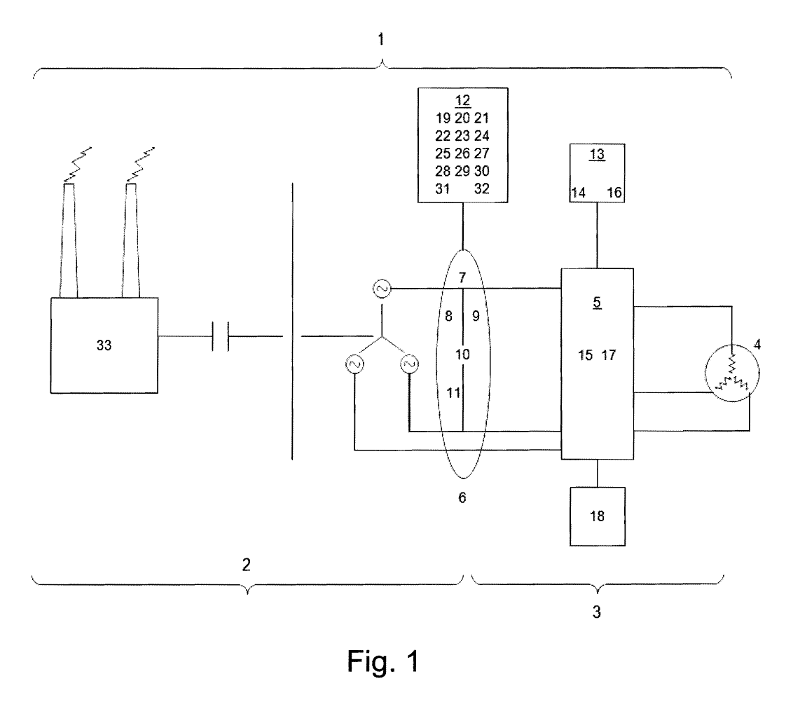

In order to understand the techniques of the present invention, it is helpful to understand both a basic machine or motor circuitry system and the mathematics of the electrical effects that occur in the circuitry. FIG. 1 illustrates a basic machine or motor circuitry system as it may be viewed in the context of the present invention. The machine or motor circuitry system can include electric machine or motor circuitry (1) that leads from a power plant (33), all the way through to the electrical machine such as a motor (4). From this diagram, it be understood that the electrical machine or motor circuitry (1) can be very expansive. The power plant (33) or other effective source may be located miles and even hundreds of miles from the actual machine or motor itself. As may be understood from FIG. 1, the electric machine or motor circuitry (1) can be characterized as having a supply path (2) and a load path (3). The supply path (2) and load path (3) can be circuitry for which a boundary is delimited by a sense location (6). It is the selection of this sense location (6) that may even define the beginning and ending points of the supply path (2), and the load path (3). For test purposes, it may even be necessary that the sense location (6) be selected carefully. This can be important because there are often fundamental differences between a fault in the supply path (2) and in the load path (3). Further, as discussed above, it can also be important to select the sense location (6) at a location for which access is convenient. Frequently, any requirement of opening and accessing an electric machine or motor circuitry (1) within a motor control center (5) is problematic. By avoiding a need for internal access to the motor control center (5), embodiments of the present invention can serve one of the goals, namely, the ability to facilitate easy access when desired. By accessing the electric machine or motor circuitry (1) at points which are already accessible or accessed, the present invention can greatly ease test efforts. As may be seen in FIG. 1, sense location (6) is a location at which some type or types of electrical effect sensor (7) may be inserted. This may be a pre-existing electrical effect sensor (7), or it may be a separate, new element. As may be understood, the electrical effect sensor (7) can be a voltage effect measurement element, a current effect measurement element, or both among other options. Considering these two elements as but examples, it can be understood that they may be configured to sense effects within, from, or caused by the supply path (2). As such, the electrical effect sensor (7) may be considered as a supply path voltage effect measurement element (8) or a supply path current effect measurement element (9). Responsive to the electrical effect sensor (7) may be some type of analyzer. The analyzer may include a variety of elements. One type of analyzer element is a configuration whereby the analyzer serves as a quantitative supply path anomaly analyzer (12).

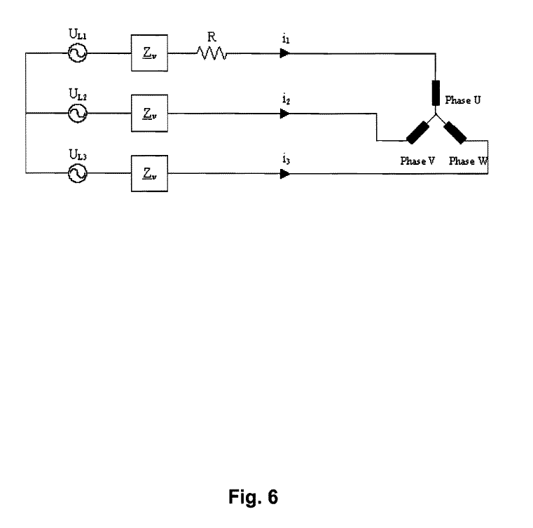

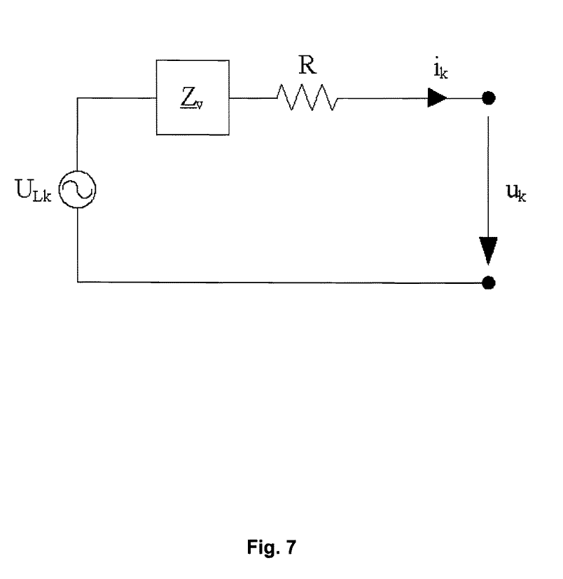

The principal of calculating upstream impedance or other anomalies can involve somewhat sophisticated mathematical analysis. FIG. 6 illustrates the traditional circuit structure of a three phase system and the AC machine or motor windings. U_{L1}, U_{L2} and U_{L3} represent ideal voltage power supplies of a three phase system where the impedance Zᵥ is the lumped upstream impedance to each phase. R represents a loose connection between the machine or motor and the supply. In this illustrative example, a wye connected machine or motor is assumed. FIG. 7 shows a similar schematic for a single phase circuit or for one of the three phases (where k is the indicator for the phase number). Any voltage difference between the machine or motor's and the source's star points can be neglected. U_{Lk} is the line-neutral voltage on the supply side and uk is the measured voltage on the machine or motor side. Zᵥ, the internal impedance of single phase power supply, is assumed to be balanced. In the illustration, R is the loose or otherwise problematic connection represented by a resistance.

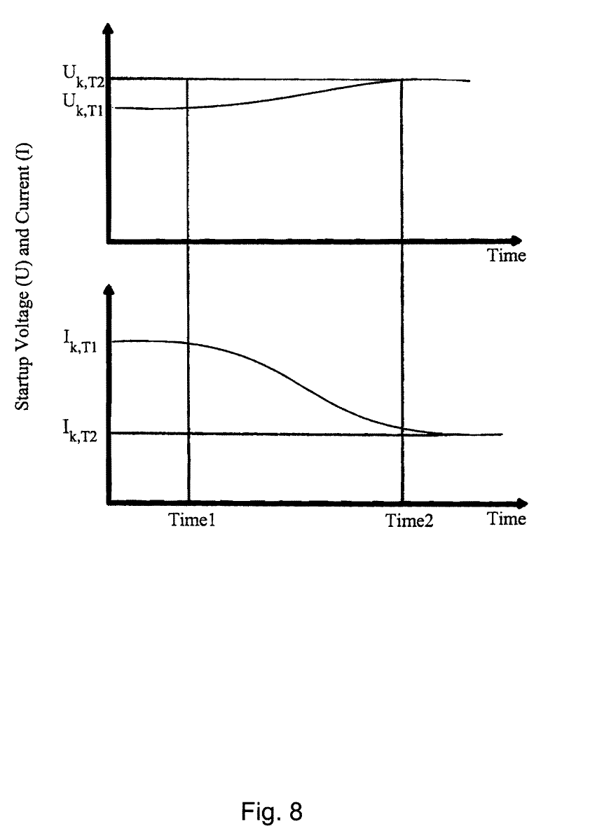

To conduct the analysis, embodiments of the invention may involve a timed waveform analysis method. This time-waveform analysis method, can use the three current and voltage waveforms captured during across-the-line startup of a three phase induction machine or motor. This technique can also offer an estimate of the contact resistance for high contact resistance faults upstream the point of connection. Significantly, by including some type of load change, certain techniques can discriminate between the upstream and downstream faults. It is even possible to calculate the severity of an upstream (and, as will be shown, a downstream) anomaly. Specifically, the fact that the voltages uk and the currents iₖ change over time, but the voltages U_{Lk} on the line side remain the same is fundamental to certain embodiments. As shown in FIG. 7 and FIG. 8, systems can be characterized by the following equations:

U_{Lk,Time1}=I_{k,Time1}(Zᵥ+R)+U_{k,Time1} (eq1)

U_{Lk,Time2}=I_{k,Time2}(Zᵥ+R)+U_{k,Time2} (eq2)

Here, the line side may be viewed as an infinite buss. Knowing that the voltage on the line side will not change, one can replace U_{Lk,Time2} with U_{Lk,Time1}.

U_{Lk,Time1}=I_{k,Time2}(Zᵥ+R)+U_{k,Time2} (eq3)

As mentioned, load changes can be used to identify anomalies. Test results can be enhanced or more accurate, if the current difference between the two time points is at least four times higher than rated current. Therefore, the time points can be chosen at the very beginning of the startup and soon after rated current is reached. Subtracting (eq3) from (eq1) eliminates U_{Lk,Time1} and results in the following:

$${\underline{Z}}_{k} = ( {\underline{Z}}_{v} + R ) = \frac{- {\underline{U}}_{k , Time 1} + {\underline{U}}_{k , Time 2}}{{\underline{I}}_{k , Time 1} - {\underline{I}}_{k , Time 2}} \qquad ( eq 4 )$$

where Zₖ is the individual impedance for every phase and k is the number of the phase.

Equation (eq4) allows calculating the upstream impedance for every phase. If there is no R, that means there is no loose connection, then a calculation of the system's impedance can be made by taking the mean of the results of (eq4) as follows:

Z_{ν}=mean(Zₖ) (eq5)

If there is a loose connection, then the calculation of the system's impedance can be made by taking the minimum of the results of Equation (eq4) as shown in (eq6).

Z_{ν}=min(Zₖ) (eq6)

As may be appreciated from this understanding, this technique permits analysis even when there are significant upstream uncertainties. For example, an anomaly in the supply path (2) can be ascertained even though there is uncertainty as to the loading or other conditions within that supply path. As shown, a supply path voltage effect from an anomaly can be ascertained. Similarly, a supply path current effect can also be ascertained. Thus, the technique can permit understanding of a supply path anomaly condition by simply measuring electrical machine or motor circuitry effects. Importantly, this can be true even though the supply path may be of an unknown character.

To measure any such effects, the sensing aspects of the invention can be fairly straightforward. For example, referring to FIG. 1, it can be seen that a variety of different sensors can be inserted at a sense location (6). The sensor(s) can sense any combination or permutation of voltage, current, magnitude, or phase. They can sense line-line effects as well as line-neutral effects. Thus, the electrical effect sensor (7) can serve as a line-line effect measurement element (10), as well as a line-neutral effect measurement element (11). Similarly, embodiments can include a line-neutral voltage effect measurement element, or more generally, a line-neutral effect measurement element (11). As mentioned above, the sense location (6) can the point at which a system can identify electrical effects that are between the supply path (2) and the load path (3) because the sense location (6) can define the beginning and ending of the two different paths. By determining at least one electrical parameter at the sense location (6), embodiments can discriminate between upstream and downstream effects. In instances where the electrical effect sensor (7) is configured to be utilized in a manner that realizes effects caused by the supply path, the electrical effect sensor (7) can serve as a supply path electrical effect sensor. Similarly, in instances where the electrical effect sensor (7) is configured to be utilized in a manner that realizes effects caused by the load path, the electrical effect sensor (7) can serve as a load path electrical effect sensor.

An important aspect of embodiments of the invention is that the sensing can be accomplished while the electric machine or motor circuitry is operational. By operationally active sensing and operationally active circuitry sensing, embodiments can permit to monitoring without interruption of service. The machine or motor circuitry can be active and in an operative configuration. In fact, as discussed later it can be seen that operational events and an operative configuration can even be preferred as it may naturally cause the load changes that may be desirable for some methods.

Further, instead of needing multiple access points as required for some existing techniques, embodiments of the invention can be based on data derived from a single access point. This can facilitate monitoring as well as sensing. In embodiments, where there is only sensing at a single location such as the sense location (6), systems can analyze both upstream and downstream faults from that single location. No longer is there a need to sense at multiple locations such as needed in the voltage drop or other existing techniques. Of course, in some systems, there may already be other sensing already existing or implemented. An advantage of embodiments of the invention is that their techniques might be analytically responsive to actually only the effects measured at that single sense location (6). By being substantially only analytically responsive, it be understood that there may be other inputs, however, those inputs may not been necessary to achieve the desired analysis. Thus, inclusion of extraneous or analytically unnecessary inputs should not be construed as avoiding a technique that is substantially only analytically responsive to a single sense location input. As mentioned above, by completely characterizing both upstream and perhaps even downstream faults from a single location, embodiments may completely avoid any need for access to the motor control center (5). Thus, the sense location (6) can be a sense location external to the motor control center circuitry. In this fashion, embodiments may include an electrical effect sensor (7) which is an external machine or motor control center circuitry sensor.

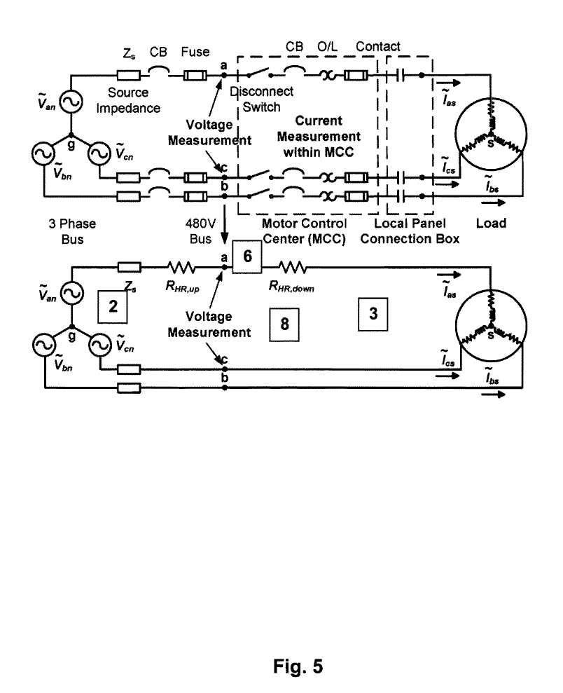

Returning to the mathematical models for a three-phase system, it can be understood that the model of a 3 phase electrical distribution system of an industrial facility with a high-R connection can be considered a basis for the analysis of the inventive techniques. In most cases, high-R connections that are serious enough to cause problems occur in one of the three phases; therefore, a high-R connection is modeled as an additional resistance, R_{HR}, in one phase, as shown in FIG. 5. The contact resistance due to high-R contacts located upstream and downstream in phase A are represented as R_{HR,up} and R_{HR,down}, respectively, as shown in the equivalent circuit of FIG. 5. It can be seen in FIG. 5 that the measured voltage is a function of the source voltages, Vₐₙ, V_{bn}, and V_{cn}, phase currents, Iₐₛ, I_{bs}, and I_{cs}, source impedance, Zₛ, and upstream contact resistance, R_{HR,up}. For a high-R connection located upstream in phase A, the voltage measurements can be mathematically expressed as (eq7), if the source line-neutral voltages, V_{ag}, V_{bg}, and V_{cg}, are measured, as follows:

\tilde{V}_{ag}=\tilde{V}ₐₙ−ZₛĨₐₛ−R_{HR,up}Ĩₐₛ

\tilde{V}_{bg}=\tilde{V}_{cb}−ZₛĨ_{bs}

\tilde{V}_{cg}=\tilde{V}_{cn}−ZₛĨ_{cs} (eq7)

As mentioned above, embodiments of the invention can at least either both upstream and downstream faults. By utilizing a load change condition, embodiments can distinguish between the two types of anomalies even though sensing at a single sense location (6). Just as comparing a change in a load path effect can be used for a supply path determination, so, too, a change in a load path effect can be determined. These determinations can reveal the existence, location, or even severity of a supply or load path fault. In fact, the very same effects that may be considered as supply path effect (whether voltage or current) can be considered a load path effect when it is utilized with the appropriate mathematics or the like to make a load path determination. Furthermore, just as the act of comparing a supply path voltage effect and a supply path current effect can be used, so, too, the act of comparing a load path voltage effect and a load path current effect can also be used.

Considering the supply path determination as an initial focus, it can be understood that embodiments may compare a change in a supply path voltage effect that takes place as a result of a load change condition. Furthermore, the supply path voltage effect can be even compared or otherwise utilized in conjunction with a supply path current effect for more precise determinations. It should be understood that each of these effects can include an effect on magnitude, angle, or some combination of the two. Thus, embodiments may act to measure a supply path parameter magnitude variation or a supply path parameter angle variation. As explained below with respect to the specific mathematics involved, these effects may be measured in a line-line manner or in a line-neutral manner.

If the source line-line voltages, V_{ab}, V_{bc}, and V_{ca} are available, the voltage measurements can be expressed as,

\tilde{V}_{ab}=\tilde{V}ₐₙ−\tilde{V}_{bn}+Zₛ(Ĩ_{bs}−Ĩₐₛ)−R_{HR,up}Ĩₐₛ

\tilde{V}_{bc}=\tilde{V}_{bn}−V_{cn}+Zₛ(Ĩ_{cs}−Ĩ_{bs})

\tilde{V}_{ca}=\tilde{V}_{cn}−\tilde{V}ₐₙ+Zₛ(Ĩₐₛ−Ĩ_{cs})+R_{HR,up}Ĩₐₛ (eq8)

If the source is delta-connected, equations similar to that shown in (eq8) can be derived by a person of ordinary skill in the art. The voltage equations shown in (eq7) and (eq8) are used for deriving the algorithm for estimating R_{HR,up} below. Of course, measurements can be taken in different manners. Embodiments can act to measure a line-neutral voltage effect, as well as a line-line voltage effect, thus, embodiments can include a line-line voltage effect measurement element as well as a line-neutral voltage effect element and the like. Each of these may serve as the appropriate voltage or current measurement element such as a supply path voltage effect measurement element (8) or a supply path current effect measurement element (9). As may be appreciated, the actual type of measurement element can be determined by the way information is used rather than the actual sensor or measurement element itself. Regardless how voltage or current variations are determined, when the variations are due to a change in the load, the embodiments can be considered as including a supply side voltage variation measurement element, a supply side current variation measurement element, or the like. Naturally, these can exist for the load side as well.

If line-to-line voltage measurements are available instead of the line-neutral voltages, the change in the voltage, delta V, between the on and off states during load startup or shutdown can be derived from (eq8), as

Δ\tilde{V}_{ab}=\tilde{V}_{ab,on}−\tilde{V}_{ab,off}=Zₛ(Ĩ_{bs,on}−Ĩ_{as,on})−R_{HR,up}ĩ_{as,on}

Δ\tilde{V}_{bc}=\tilde{V}_{bc,on}−\tilde{V}_{bc,of}=Zₛ(Ĩ_{cs,on}−Ĩ_{cs,on}−Ĩ_{bs,on})

Δ\tilde{V}_{ca}=\tilde{V}_{ca,on}−\tilde{V}_{ca,off}=Zₛ(Ĩ_{as,on}−Ĩ_{cs,on})+R_{HR,up}Ĩ_{as,on} (eq9)

It can be seen in (eq9) that the upstream impedance, Zₛ and R_{HR,up}, can be calculated from the measured line voltages and currents. If the change in line voltage is divided by the difference in currents, the “upstream impedance” can be derived from (eq9), as shown in the following.

$${Z}_{s} + \frac{{R}_{HR , up} ∠30°}{\sqrt{3}} \approx \frac{Δ {\tilde{V}}_{ab}}{( {\tilde{I}}_{bs , on} - {\tilde{I}}_{as , on} )} \\ {Z}_{s} = \frac{Δ {\tilde{V}}_{bc}}{( {\tilde{I}}_{cs , on} - {\tilde{I}}_{bs , on} )} \\ {Z}_{s} + \frac{{R}_{HR , up} ∠30°}{\sqrt{3}} \approx \frac{Δ {\tilde{V}}_{ca}}{( {\tilde{I}}_{as , on} - {\tilde{I}}_{cs , on} )} \qquad ( eq 10 )$$

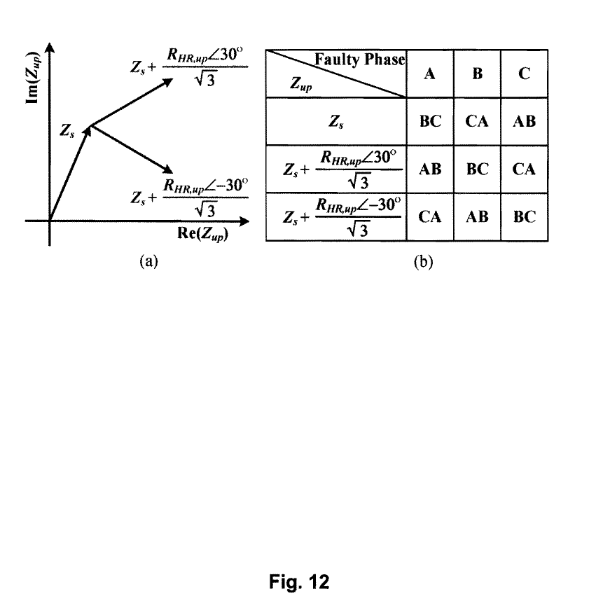

It can be seen in (eq10) that the upstream impedances for all three phases are equal to Zₛ, if all three phases are healthy, since R_{HR,up} is zero. If a high-R contact is present in phase A, the upstream impedances obtained from the phase AB, BC, and CA voltage measurements are different, as shown in (eq10). The three upstream impedances for the case when a high-R fault is present in phase A can be represented in a complex plane, as shown in FIG. 12(a). It can be seen in this figure that the pattern of the three phase upstream impedance estimates can be used to determine the existence of the upstream high-R contact. Equations for cases when the fault is located in phase B and C can also be derived similarly as the phase A case shown in (eq8), (eq9), and (eq10). The table in FIG. 12 summarizes the pattern of the upstream impedances obtained from phase AB, BC, and CA voltages for cases when the high-R fault is located in phase A, B, and C, respectively. It can be seen in FIG. 12(b) that the location or phase of the fault can also be determined from the three phase upstream impedance pattern. The equation for estimating R_{HR,up} for determining the fault severity when the fault is in phase A can be derived from (eq9)-(eq10) as

$${\hat{Z}}_{s} = \frac{Δ {\tilde{V}}_{bc}}{( {\tilde{I}}_{cs , on} - {\tilde{I}}_{bs , on} )} \\ {\hat{R}}_{HR , up} = \frac{( - Δ {\tilde{V}}_{ab} - {\hat{Z}}_{s} ( {\tilde{I}}_{as , on} - {\tilde{I}}_{bs , on} )}{{\tilde{I}}_{as , on}} \qquad ( eq 11 )$$

The value of Zₛ may be calculated from the phase BC measurements first, and used for estimation of R_{HR,up}, as shown in (eq11). (Equations for estimating R_{HR,up} for phase B and C faults can be derived similarly as a person of ordinary skill in the art would well understand.)

An aspect through which embodiments of the invention can significantly distinguish themselves is that of sensitivity. Embodiments of the present invention can be so sensitive as to permit not only identification of existing anomalies or faults but even identification of merely incipient anomalies—that is those that exhibit slight abnormal indicia but which are as yet not presenting any type of hazard or risk. As explained mathematically, embodiments can utilize and ascertain the nature and existence of an anomaly quantitatively. Thus, an analyzer which utilizes the values from the electrical effect sensor (7) can be considered a quantitative anomaly analyzer (12). This quantitative anomaly analyzer (12), can be a quantitative supply path anomaly analyzer or a quantitative load path anomaly analyzer. By making determination in a manner that affords unusual sensitivity, this analyzer can even serve as an incipient fault analyzer.

One of the aspects that permits unusual sensitivity for embodiments of the invention, is the fact that the embodiments can use a changing the load condition as part of their determination method. This changing load condition can be normative or an artificial insertion to the operation of the machine. In experiencing a normative operational load change condition, no actions to effect a change is necessary; the normal operation of the machine or motor circuitry will enough to provide the necessary changes. One of the most extreme and in fact useful changes in load condition that can be used is the normal turning on and turning off of the machine or motor itself. Similarly, a change such normal operation as the switching on and off of power factor circuitry capacitors or the like can be used. These changes can actually be used to aid in identifying, quantifying, and even discriminating real or potential faults within the electric machine or motor circuitry (1). Thus, embodiments can include a load change implementor (13). This load change implementor (13), can be merely the natural operation of the electrical machine or motor circuitry (1) or motor (4). The normally operative switching on and off of the electrical machine or motor (4) can be considered the load change implementor (13). When utilized in conjunction with some sort of load change condition, embodiments may be considered as having the electrical effect sensor (7) as actually serving as a load change condition sensor, that is a sensor that notices effects occurring as a result of the load change condition itself. This load change condition sensor can act to discern effects that may exist when the electrical machine or motor circuitry (1) merely experiences some type of load change condition, be that a natural or normative operational change, or an artificial change such as the switching in or out of some type of circuitry or the turning on or off of some type of circuitry.

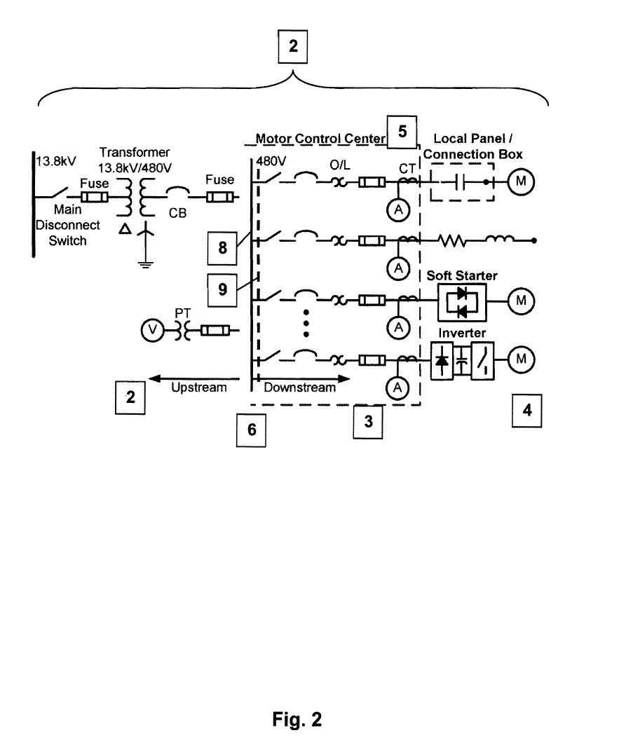

Similarly, the startup (and by analogy shut down) behavior of three-phase induction machine or motors can be mathematically understood. For the start up example, FIG. 8 illustrates the RMS voltage and RMS current behavior of a three phase induction machine or motor during startup. The voltages are low at the beginning and rise, while the currents drop. High slip during startup causes currents that are six to ten times higher than rated current. The voltage change in this example is about 10%; this percentage change strongly depends on the short-circuit capability of the system. As suggested above, the fault can be viewed as merely a high-R upstream connection. In such instances, the typical waveform of the source voltage and current magnitude and phase angle under startup and shutdown of the load are shown in FIG. 10. It should be noted in this figure that the voltage of the common bus can always be measured whether the load is on or off, since there are other loads operating, as shown in FIG. 2. The degree of voltage or current variation may depend on the type of load and how it is started or shut down. For instance, the starting current can be as high as 6˜10 times the rated current for a mains—fed machine or motor, but is in the same order of magnitude as the rated current for a soft-started machine or motor or R-L load, as shown in FIG. 10. The dip in the voltage is due to the voltage drop across the source impedance, and is proportional to the current and contact resistance. The change in the voltage, delta V, when the load is started or shut down can be derived from (eq7), as shown in (eq12), where subscripts on and off represent the “state” of the load.

Δ\tilde{V}_{ag}=\tilde{V}_{ag,on}−\tilde{V}_{ag,off}=−ZₛĨ_{as,on}−R_{HR,up}Ĩₐₛ

Δ\tilde{V}_{bg}=\tilde{V}_{bg,on}−\tilde{V}_{bg,off}=−ZₛĨ_{bs,on}

Δ\tilde{V}_{cg}=\tilde{V}_{cg,on}−\tilde{V}_{cg,off}=−ZₛĨ_{cs,on} (eq12)

It can be seen in (12) that the upstream impedance, Zₛ and R_{HR,up} can be calculated from the V_{abcg,on}, V_{abcg,off}, and I_{abcs,on} measurements for each phase during startup or shutdown of the load. The change in the load voltage between the load off state and startup (su) can be used for estimation of R_{HR,up} and Zₛ. The analytic equation for estimating R_{HR,up} and Zₛ can be derived from (12), as shown in (13).

\hat{R}_{HR,up}+\hat{Z}ₛ(\tilde{V}_{ag,off}−\tilde{V}_{ag,su})/Ĩ_{as,su}

\hat{Z}ₛ=(\tilde{V}_{bg,off}−\tilde{V}_{bg,su})/Ĩ_{bs,su}=(\tilde{V}_{cg,off}−\tilde{V}_{cg,su})/Ĩ_{cs,su} (eq13)

It can be seen in (eq13) that R_{HR,up} can be estimated from the phase with the largest impedance estimate (faulty phase) by subtracting the Zₛ estimate from the phase with the lowest impedance estimate (healthy phase). Similarly, R_{HR,up} can also be estimated from the change in the load voltage between steady state (ss) operation and the load off state whenever the load is shutdown, as shown in (eq14).

\hat{R}_{HR,up}+\hat{Z}ₛ=(\tilde{V}_{ag,off}−\tilde{V}_{ag,ss})/Ĩ_{as,ss}

\hat{Z}ₛ=(\tilde{V}_{bg,off}−\tilde{V}_{bg,ss})/Ĩbs,ss=(\tilde{V}_{cg,off}−\tilde{V}_{cg,ss})/Ĩ_{cs,ss} (eq14)

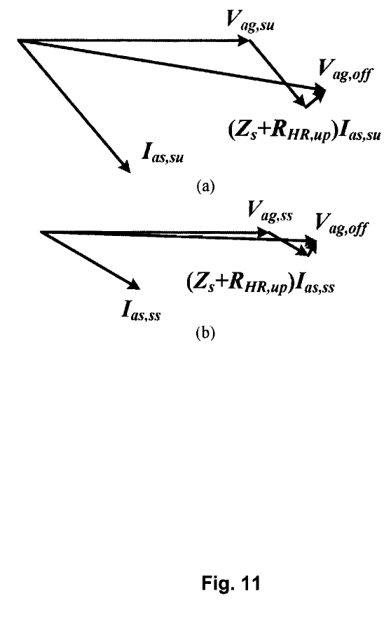

The phasor diagram representation of the change in source voltage and current when a high-R connection is present upstream in phase A under startup and shutdown are summarized in FIG. 11(a)-(b), respectively. It can be observed in FIG. 11 and (eq13)-(eq14) that the resolution of the R_{HR,up} can be improved if the change in voltage (or current) is higher. Similarly, it is advantageous to estimate R_{HR,up} when the starting current is high during startup or when the load current is high during shutdown.

By permitting use with operationally active circuitry, embodiments can use ordinary operational load changes for the machine or motor. In such embodiments, electrical effect sensor (7) can be viewed as an operationally active circuitry measurement element. This, of course, can be an operationally active supply path electrical effect sensor and an operationally active load path electrical effect sensor. Naturally, the changes which may be needed can be specifically switched or artificial events as well. These events can be caused by sensing software or by an analyzer such as at a predetermined time. In this manner, embodiments can act to switch an operational condition load change. Thus, there can be included an operational condition load change condition switch element (14). This switch element can be a normative operational load change condition switch element or a separately provided one. Furthermore, whether or not in a normative operational mode, the load change can be a known load change so that specific determinations can be made based upon the size and anticipated effect of the load change. Embodiments can thus experience a known load change condition. This quantitatively known load change condition can of course be a machine or motor start up condition as well as a machine or motor shut down condition. It can also be a known change in the power factor circuitry (15). In this manner, embodiments can experience a machine or motor power factor change condition. In either of the arrangements, a load change implementor (13) can be a quantitatively known load change condition implementor. Furthermore, the switch element may be a machine or motor start up condition switch element (16), a machine or motor shutdown condition switch element (16), a machine or motor power factor change condition switch element (17), or some other type of switch arrangement.

As mentioned above, comparisons between phases can be conducted. Comparisons between phases can also be conducted whereby a known condition can be reasoned to cause a known effect. From these examples, it can be understood how embodiments can utilize historical data. Machine or motor operative historical data information can be stored or available to embodiments of the invention. This can be particularly beneficial in a single phase electric machine or motor power circuit where interphase comparisons may not be possible. By storing data, embodiments may include memory elements such as a machine or motor operational data memory (18). The motor operational data memory (18) can be located in any location where information can be accessible, such as within the machine or motor control center, or in some separate analyzer or other facility or device. Performance data can be stored for access as part of the test operation. This data memory may be a machine or motor operative historical data memory such as a memory that includes data from prior events or even one that provides information from merely the beginning of a load change condition.

As may be appreciated from the above mathematical examples, comparisons can be conducted pre-and post- a load change condition. These comparisons can be of voltage, current, magnitude, or angles that occur before and perhaps after the load change condition occurs. By proper programming or configuration, the analyzer can thus function as a pre-and post-load change condition analyzer (19). This pre-and post-load change condition analyzer (19), can function as a pre-and post-load change condition voltage analyzer, a pre-and post-load change condition current analyzer, a pre-and post-load change parameter angle analyzer, or even a pre-and post-load change parameter magnitude analyzer. As mentioned above, the load change itself can be most beneficial if it is a substantial load change. By experiencing a substantial load change condition, greater sensitivity can be facilitated. For example, if the change is greater than the rated current of the machine or motor, that change can more noticeably evidence effects. Furthermore, by experiencing a greater than four times rated current load change condition, even more sensitivity can be available. Thus embodiments can have a greater than rated current load change implementor or even a greater than four times rated current load change implementor as a configuration for the change implementor (13). From some perspectives, it can be understood that if the current difference between the two time points is at least four times higher than rated current, better results can be available. Therefore, the time points could be chosen at the very beginning of the startup and soon after rated current is reached. Subtracting (eq3) from (eq1) eliminates ULk,Time1 and results in the following:

$${\underline{Z}}_{k} = ( {\underline{Z}}_{v} + R ) = \frac{- {\underline{U}}_{k , Time 1} + {\underline{U}}_{k , Time 2}}{{\underline{I}}_{k , Time 1} - {\underline{I}}_{k , Time 2}} \qquad ( eq 15 )$$

where Zₖ is the individual impedance for every phase and k is the number of the phase. As may be understood from this relationship, the pre-and post-load change condition analyzer can analyze individual or combinations of voltage, current, magnitude, and angle effects. It can compare a fault angle before and after the load change condition, the voltage magnitude before and after the load change condition, current angle before and after the load change condition, and the current magnitude before and after the load change condition for any individual or in between various phases. Conducting these steps and providing the type of analyzer and monitoring systems can be implemented in any particular embodiment. Naturally any combinations or permutations of any of the above can be used as well.

Embodiments can act to ascertain if a supply path anomaly condition exists or if a load path anomaly condition exists. The analyzer can be configured as a supply path anomaly analyzer (20) as well as a load path anomaly analyzer. In making the analysis, it can also estimate a condition. For example, at its most basic level, the fault can be estimated to be a purely resistive fault. With or without such estimations, the analyzer can be configured as current analyzer, a voltage analyzer, a current magnitude analyzer, a voltage magnitude analyzer, a current angle analyzer, or even a voltage angle analyzer. The mathematics of the various methods show that both magnitude and angle can yield important and usable information. Thus, the analyzer can serve as an electrical magnitude variation analyzer (21) or as an electrical angle variation analyzer (22) through which analysis can ascertain a change in magnitude or angle of any of parameters. One of the fundamental aspects of the method is that it can utilize interphase comparisons to identify a bad phase. These changes can be conducted between phases so the action of interphase comparing can be conducted. This can be particularly valuable in three or other phase systems where there is multiphase sensing. In this fashion, embodiments can be considered as having an analyzer that represents an interphase analyzer (23) or even an interphase comparator (24) by conducting comparisons between information from the differing phases.

By estimating that anomalies are generally purely resistive, embodiments can be configured to compare to a low resistance phase measurement. By conducting a low resistance phase comparison, the analyzer can be configured as a low resistance phase comparator (25) through which analysis can identify a low resistance phase and therefore deduce that the higher resistance phase is actually that in a condition of experiencing a failure or incipient failure.

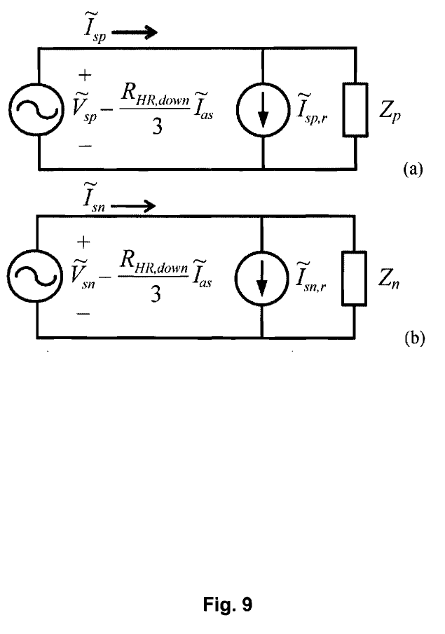

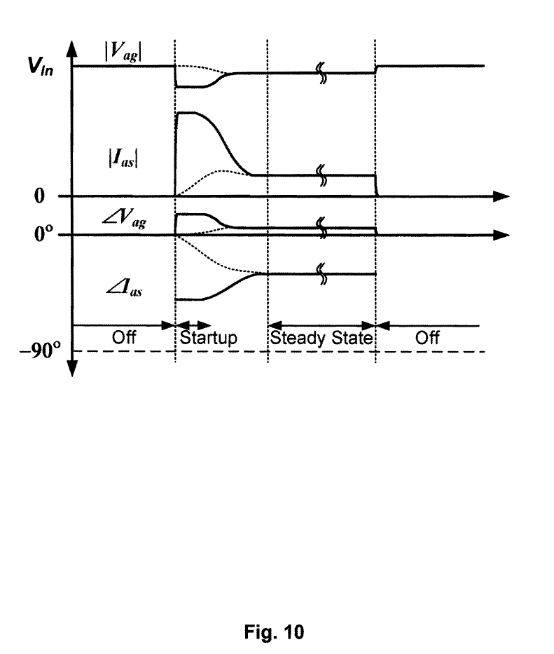

Especially for load path faults, anomaly determinations can be accomplished by measuring sequence currents such as a negative sequence current. To some extent, positive and zero sequence currents can also be used as may be understood. The use of negative sequence current measurement or analysis can be understood as shown in a FIG. 9(b). Here, an analytical equation for the negative sequence current, Iₛₙ, can be derived as

$${\tilde{I}}_{sn} = \frac{{\tilde{V}}_{sn}}{{Z}_{n}} - \frac{{R}_{HR , down} {\tilde{I}}_{as}}{3 {Z}_{n}} + {\tilde{I}}_{sn , r} \qquad ( eq 16 )$$

It can be seen in FIG. 9(b) and (eq16) that Iₛₙ is a phasor sum of the contributions due to source voltage asymmetry (1st term), downstream high-R connection (2nd term), and residual asymmetry (3rd term), which is due to load or measurement imperfections or faults. The algorithm for estimating R_{HR,down} in V is derived based on the Iₛₙ equation shown in (eq16). Sequence currents can be used in for both upstream and downstream detection, and negative sequence currents can be used for the load path anomaly as well as to some extent the supply path anomaly determinations. Sequence current can be measured directly or can be determined from existing sensors. Thus, systems and embodiments can include sequence current measurement elements that may or may not be the actual sensors themselves; the analyzer can serve as a sequence current analyzer (27). The specific phase comparisons or phase indications which evidence a voltage or current effect can be used to locate the fault or anomaly by at least identifying the specific phase involved. Embodiments can conduct locationally identifying an anomaly. The equations for determining the existence, location, and severity of the fault when the source is delta-connected can also be derived in a similar fashion from manipulation of the voltage equation as in the Y-connected case presented in this section. It can be seen in FIG. 2 that the voltage drop across the upstream impedance can also be influenced by startup, shut down, or change in other loads connected downstream. Therefore, the current flow in the other loads must be monitored to check if they are under steady state operation before applying the proposed high-R contact detection techniques. Of course, embodiments can include a supply path anomaly locational identifier, a load path anomaly locational identifier, a severity indicator, or can conduct the action of severity assessing an actual or potential fault.

In the field there is always the possibility of measurement errors caused by the system itself, such as potential transformers (PT) and current transformers (CT) already installed to monitor high voltage systems. So knowing the sensitivity of the method is very important. Sensor errors are typically time-invariant, so adding an error to (eq4) can be represented by a multiplication of a factor δ. δ includes the error readings for voltages and currents as shown in the following:

$$\frac{- {δ}_{U} {\underline{U}}_{k , Time 1} + {δ}_{U} {\underline{U}}_{k , Time 2}}{{δ}_{I} {\underline{I}}_{k , Time 1} - {δ}_{I} {\underline{I}}_{k , Time 2}} = \frac{- {\underline{U}}_{k , Time 1} + {\underline{U}}_{k , Time 2}}{{\underline{I}}_{k , Time 1} - {\underline{I}}_{k , Time 2}} \cdot \frac{{δ}_{U}}{{δ}_{I}} ⇒ δ = \frac{{δ}_{U}}{{δ}_{I}} \\ \frac{- {\underline{U}}_{k , Time 1} + {\underline{U}}_{k , Time 2}}{{\underline{I}}_{k , Time 1} - {\underline{I}}_{k , Time 2}} δ = ( {\underline{Z}}_{v} + R ) δ = {\underline{Z}}_{k} δ \qquad ( eq 17 )$$

The resistance may be calculated out of (eq19) on which δ will have the following effect.

max(Re(Zₖδ))−min(Re(Zₖδ))=δR (eq18)

(eq18) may show that a measurement error of a certain percentage will result at max in less than double of that percentage error in the resistance. This can be useful in assessing the accuracy of measuring a severity of an actual or potential fault in those embodiments that include a supply path anomaly severity analyzer or load path anomaly severity analyzer.

Determinations can be based on asymmetry in phases or otherwise and so there can be a step of sensing an asymmetry condition and even sensing a phase asymmetric voltage or the like. The voltage drop across the high-R connection located either upstream or downstream results in an asymmetric voltage input to the 3 phase load. This results in a negative sequence current, Iₛₙ, flow that could be detrimental to many loads (especially induction machine or motor loads). It can be shown that the positive (or per-phase) and negative sequence steady state equivalent circuits for a 3 phase load can be derived as a function of the downstream contact resistance, R_{HR,down}, as shown in FIG. 9. In the equivalent circuits, Vₛₚ and Vₛₙ represent the positive and negative sequence voltages of Vₐₛ, V_{bs}, and V_{cs}, where s represents the neutral of the load, and Iₛₚ and Iₛₙ represent the positive and negative sequence currents of Iₐₛ, I_{bs}, and I_{cs}. The positive and negative sequence quantities in FIG. 5 can be calculated from the three phase voltage or current measurements whether they are phase or line quantities. Impedances Zₚ, Zₙ represent the positive and negative sequence impedances, and they can be identical (R-L load) or different (induction machine or motor) depending on the load. It should be noted that only the asymmetry due to the downstream contact problems are modeled in FIG. 9, since the upstream contact problems are already reflected in Vₛₚ and Vₛₙ as can be seen in (eq7) and (eq8).

By sensing a phase asymmetric effect, embodiments can be considered as having an asymmetry condition analyzer (28). This may be an asymmetry in the voltage, the current, a magnitude, an angle, or even within individual phases. Embodiments can therefore include a voltage phase asymmetry condition analyzer, a current phase asymmetry condition analyzer, or the like. This asymmetry condition can be identified by using negative sequence current analysis, by conducting a low resistance phase comparison, or otherwise. As mentioned above, the low resistance phase comparison can be used to deduce a healthy phase such as by determining that a phase with low resistance is a healthy phase and a phase with a higher resistance is an unhealthy phase. This can also be deduced by using historical information as well. Thus embodiments can function to estimate an individual phase condition such as by estimating a supply path power circuitry condition, estimating a purely resistive supply path anomaly, or the like.

The aspect of estimating a purely resistive fault condition can be used because it is likely that a loose connection is a pure resistance without an imaginary part. Therefore, the resistance R can be calculated by subtracting the real parts of the results of (4) for all three phases as shown in (eq19).

R=max(Re(Zₖ))−min(Re(Zₖ)) (eq19)

In order to find out which phase has the resistance R, i.e. the loose connection, it is most likely the phase with the maximum of the results of (eq4). To find out whether the resistance is on the up- or downside of the measurement, only a relative statement can be made. If the calculated resistance measured directly at the machine or motor is much higher than the calculated resistance measured further upstream, then it is most likely that the resistance is between those measurement points. By estimating a supply or load path power circuitry condition, such as estimating a purely resistive load path anomaly, embodiments can include a healthy phase deduction element (29). This can be in individual phase anomaly estimator, a supply path power circuitry anomaly estimator, a supply path pure resistance anomaly estimator, a load path power circuitry anomaly estimator (30), or a load path pure resistance anomaly estimator, to name a few. Further, as may be appreciated from above, embodiments can conduct comparing an interphase voltage variation, comparing an interphase current variation, a pre- and post-load change condition voltage and current comparison, a voltage magnitude comparison, or the like. For example, by measuring a supply path voltage variation, the system can include an interphase voltage comparator, a voltage change analyzer, a voltage analyzer, a voltage magnitude variation measurement element, or the like. Similarly, there can be a current angle comparison, measuring a supply path current variation, an interphase current comparator, a current analyzer, and even a current angle variation measurement element, to name a few.

One aspect for which embodiments of the present invention can provide significant advantage is in the ability to locate and quantify the severity of a potential anomaly. In fact, sensitivity can be great enough that it may be possible to determine an incipient anomaly on either the supply path or the load path. By sensing merely a slight increase in resistance or the like, embodiments can be configured to determine that an anomaly is developing. Thus, the analyzer can serve as an incipient supply path anomaly analyzer (31) or an incipient load path anomaly analyzer. Slight changes in resistance can be determined be the beginning so a problem can be rectified and a maintenance action can be taken. Importantly, this is even possible with only one substantive sense location input.

One aspect that can facilitate accurate measurements can be the inclusion of a steady state in the load path. After experiencing the desired load change condition, embodiments can assure that the load path is in a relatively steady state to make an appropriate change effect determination so that the accurate quantitative calculations can be made. Thus, the analyzer can provide input to or coordinate operation with the motor control center (5) or and other aspect. To make sure that either through proper artificial control or merely by watching for an appropriate operational condition, a steady state load can exist to facilitate the determinations. Software subroutines or switch configurations and the like can serve as a load side steady state operational condition assessment element.

Referring to FIG. 1, it can be understood how one example of an embodiment of the invention is configured for three-phase system. Naturally, other phase numbers are possible, and embodiments can be configured to address a single phase or a multiphase system. With respect to the single phase system, it may be understood that it may be important to utilize historical data as there may be no interphase comparison possible. Historical data can be used continuously and may be fairly contemporaneous data such as that taken right before the change condition. It can also be more long lived data that evidences operational parameters from a long time ago such as a prior turn on or the like. It can be helpful to have a continuous and automated system so that constant comparisons with a prior operating conditions or constant monitoring can occur. The historical data can also be helpful to aid in distinguishing the location of a potential anomaly such as in the supply path or in the load path. To determine anomaly location, it can be seen in the mathematical models that the voltage measurements may be directly influenced by high-R connections located upstream, whereas voltage measurements may not be influenced by downstream problems (current changes with downstream high-R contacts). Therefore, a different algorithm can be used depending on where the poor contact is located. For upstream high-R contacts, the value of R_{HR,up} is estimated by comparing the variation in the voltage under startup and shutdown of the load. The change in the negative sequence current can be monitored for estimating R_{HR,down} for poor contact problems located downstream. Two algorithms can be employed to provide automated monitoring of upstream and downstream high-R contacts and can be implemented using existing voltage and current measurements.

If a high-R connection is located downstream, the voltage measurement is not influenced, and the method presented above cannot be used. Since the negative sequence current changes with a downstream high-R contact as shown in FIG. 9, the change in Iₛₙ can be used for monitoring the change in R_{HR,down}. The positive sequence current may also change with a poor contact, but Iₛₙ may be one considered for monitoring, since Iₛₚ also changes with load (Zₚ is load dependent) for induction machine or motors, and it is difficult to distinguish what is causing the change in Iₛₚ.

A downstream high-R contact located downstream can cause the current to be unbalanced. The negative sequence current, Iₛₙ, can be an indicator of current unbalance and can therefore used as an indicator of downstream contact problems. As indicated in FIG. 1, downstream or load path anomaly sensing can occur even from a single sense location (6). Thus, the same sensors can be used as load path of sensors as well as the supply path sensors. The voltage effect measurement element and the current effect measurement element can be deemed to exist as load path measurement elements merely by applying the perspective of the downstream effects so these sensors may serve as load path electrical effect measurement elements. Similar to the supply path determined variations, the load path determinations can compare interphase variations of voltage, current, magnitude, angle, and any combinations or permutations of these. These comparisons can also be conducted pre-and post a load change condition. Furthermore, the analyzer can serve as a pre-and post-load change condition analyzer (32). As may be appreciated from the above, the load path analyzer can even be responsive to the supply path sensors.

It has been shown in prior work that the negative sequence current due to high-R contacts located downstream, for a high-R contact in phase A can be derived as:

$${\tilde{I}}_{sn , HR} = - \frac{{R}_{HR} {\tilde{I}}_{as}}{3 {Z}_{n}} \qquad ( eq 20 )$$

It can be seen that the negative sequence current is proportional to the contact resistance (Rₕᵣ) and current magnitude (Iₐₛ)−Zₙ is the negative sequence impedance of the machine or motor. For an ideal case where Iₛₙ is due to circuit problems, the contact resistance can be calculated from Iₐₛ, Iₛₙ, and Zₙ as shown in (eq21).

$${\hat{R}}_{HR} = - \frac{3 {Z}_{n}}{{\tilde{I}}_{as}} {\tilde{I}}_{sn} \qquad ( eq 21 )$$

However, in reality, due to non-idealities in the system, the actual measured negative sequence current, Iₛₙ for a 3 phase induction machine or motor load can be expressed as,

$${\tilde{I}}_{sn} = \frac{{\tilde{V}}_{sn}}{{Z}_{n}} + {\tilde{I}}_{sn , HR} + {\tilde{I}}_{sn , r} = \frac{{\tilde{V}}_{sn}}{{Z}_{n}} - \frac{{R}_{HR} {\tilde{I}}_{as}}{3 {Z}_{n}} + {\tilde{I}}_{sn , r} \qquad ( eq 22 )$$

It can be seen that Iₛₙ is a phasor sum of the contributions due to source voltage asymmetry (1^{st} term), downstream high-R connection (2^{nd} term), and residual asymmetry (3^{rd} term). The first term is due to the fact that the voltage is not balanced; the second term is because of the high-R contact; and the third term is due to the inherent asymmetry in the machine or motor or measurement system due to imperfections or faults. Therefore, if the contact resistance is estimated based on the Iₛₙ measurement, the estimate can be expressed as (eq23), and it can be seen that there will be an error (eq24) due to the supply voltage unbalance and inherent motor asymmetry.

$$\begin{matrix}{\hat{R}}_{HR} = \frac{3 {Z}_{n}}{{\tilde{I}}_{as}} ( \frac{{\tilde{V}}_{sn}}{{Z}_{n}} - \frac{{R}_{HR} {\tilde{I}}_{as}}{3 {Z}_{n}} + {\tilde{I}}_{sn , r} ) & ( eq 23 ) \\ Error ( {\hat{R}}_{HR} ) = \frac{3 {Z}_{n}}{{\tilde{I}}_{as}} ( \frac{{\tilde{V}}_{sn}}{{Z}_{n}} + {\tilde{I}}_{sn , r} ) & ( eq 24 )\end{matrix}$$

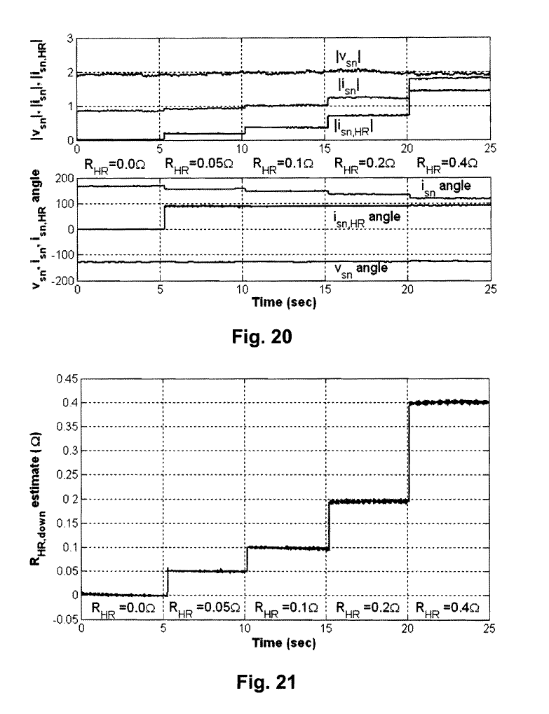

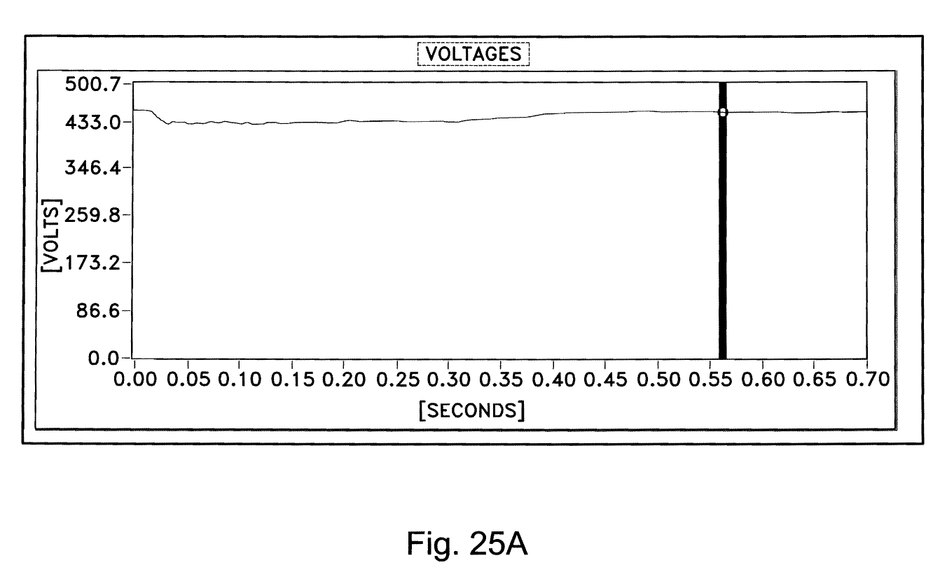

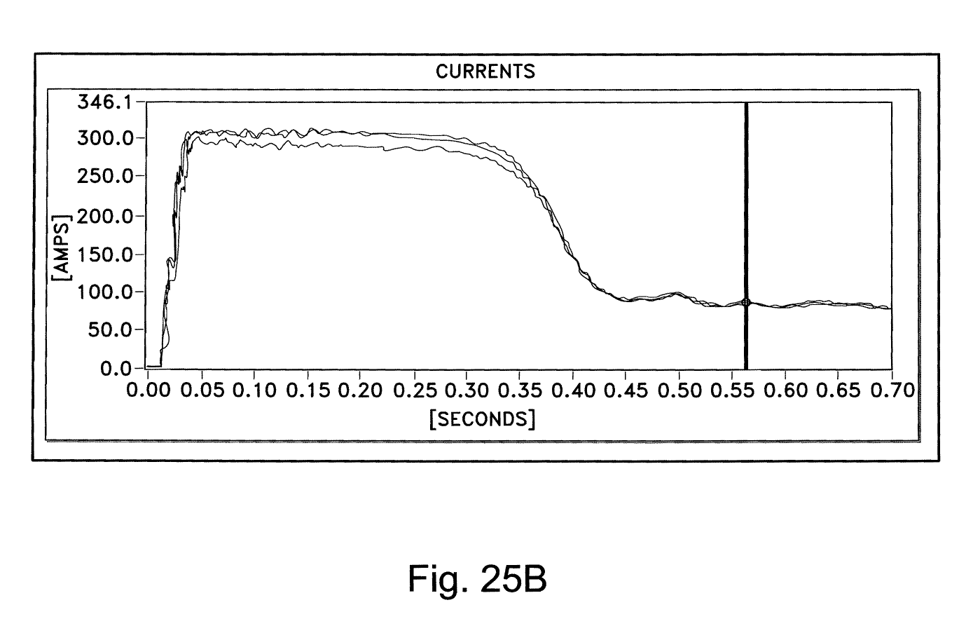

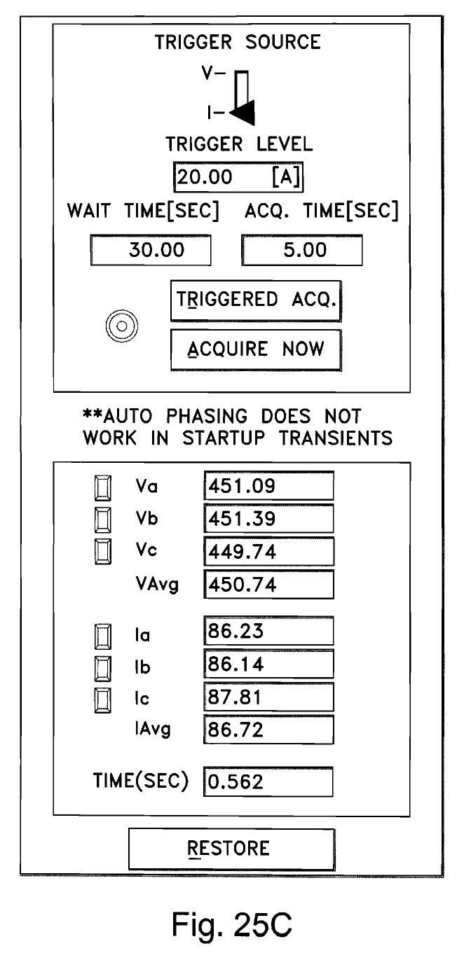

In implementing an algorithm for detecting downstream high-R connections based on Iₛₙ under steady state operation can require that the value of Zₙ and I_{sn,r} be known somewhat precisely to obtain an accurate estimate of R_{HR} since they are comparable to the Iₛₙ measurement (or I_{sn,HR}). That Iₛₙ and I_{sn,HR} are comparable can be seen from FIG. 20. However, if this model is applied during startup, the I_{sn,HR} component can be dominant in the Iₛₙ measurement, since the magnitude of the starting current Iₐₛ is large, as can be seen in (eq21) and FIG. 25. The startup current is 6-10 times larger than the rated current making the 2^{nd} term larger than the 1^{st} and 3^{rd} terms in (eq23). The negative sequence impedance can be easily obtained by calculating the impedance during startup. The motor impedance is equal to the negative sequence impedance if the slip is equal to 1 during startup. The first term due to source voltage asymmetry can be independent of stator current magnitude since the negative sequence voltage, Vₛₙ, is fixed and the negative sequence impedance, Zₙ, is load (slip) independent. The third term due to inherent asymmetry in the machine or motor/measurement system can also be independent of stator current. Therefore, it can be assumed that Iₛₙ and I_{sn,HR} are roughly the same with small error, as shown in (eq25).

$${\tilde{I}}_{sn} \approx {\tilde{I}}_{sn , HR} \approx - \frac{{R}_{HR} {\tilde{I}}_{as}}{3 {Z}_{n}} \qquad ( eq 25 )$$

An example of this type of determination is indicated in FIG. 25. It can be seen in FIG. 25 that Iₛₙ is large during the transient, but small in steady state. This indicates that the second term is significant during the startup transient.

By sensing any combination of a load path voltage effect, a load path current effect, a load path magnitude effect, and a load path angle effect, the desired determinations can be made. The maintenance can be based on variations that compare pre-and post-load change conditions and can include the type of sensing that occurs on the supply path for the load path. As appreciated from the above, a particularly useful aspect is that of the negative sequence current effects from the load path can be sensed and analyzed.

An analytical equation for the negative sequence current component due to a downstream high-R contact located in phase A can be derived from (eq16) after compensating for the non-idealities in the system due to supply voltage unbalance and inherent system asymmetry as,

$${\tilde{I}}_{sn , HR ( A )} = {\tilde{I}}_{sn} - \frac{{\tilde{V}}_{sn}}{{Z}_{n}} - {\tilde{I}}_{sn , r} = \frac{- {R}_{HR} {\tilde{I}}_{as}}{3 {Z}_{n}} \qquad ( eq 26 )$$

where (A) represents fault in phase A. If a downstream high-R connection is present in phase B or C, it can be shown that an expression for the Iₛₙ component due to the poor contact can be derived as shown in (eq27).

$${\tilde{I}}_{sn , HR ( B )} = \frac{- {R}_{HR} {a}^{2} {\tilde{I}}_{bs}}{3 {Z}_{n}} \\ {\tilde{I}}_{sn , HR ( B )} = \frac{- {R}_{HR} a {\tilde{I}}_{cs}}{3 {Z}_{n}} \qquad ( eq 27 )$$

It can be seen in (16) that the value of Zₙ and I_{sn,r} must be known to obtain an accurate estimate of R_{HR,down}. The value of Zₙ can be easily measured whether the load is a machine or motor or R-L circuit, but the value of I_{sn,r} is unknown since it depends on load and measurement system asymmetry. The value of Iₛₙ can be estimated when the electrical distribution system is “healthy” when R_{HR,down}=0 as,

$${\tilde{I}}_{sn , r} = {\tilde{I}}_{sn} - \frac{{\tilde{V}}_{sn}}{{Z}_{n}} {\vert}_{healthy} \qquad ( eq 28 )$$

From (eq26)-(eq27), it can be seen that the magnitude or severity of an anomaly, such as I_{sn,HR} can be used for detecting the existence of high-R connections since it is proportional to R_{HR}. It can also be seen from (eq26)-(eq27) that the angle of Iₛₙ can be used for determining which phase the high-R connection is present (fault location), if |Iₛₙ| exceeds a preset threshold, as shown in (eq29).,

$$∠ {\tilde{I}}_{sn , HR} = \{ \begin{matrix}( {180}^{0} + ∠ {\tilde{I}}_{as} - ∠ {Z}_{n} ) & ( Fault in Phase A ) \\ ( {180}^{0} - {120}^{0} + ∠ {\tilde{I}}_{bs} - ∠ {Z}_{n} ) & ( Fault in Phase B ) \\ ( {180}^{0} + {120}^{0} + ∠ {\tilde{I}}_{cs} - ∠ {Z}_{n} ) & ( Fault in Phase C )\end{matrix} \qquad ( eq 29 )$$

Once the fault is detected from |Iₛₙ| and faulty phase is known, the value of R_{HR} can be estimated from (eq27) to indirectly assess the severity of the fault.

$${R}_{HR} = \{ \begin{matrix}\vert - 3 {Z}_{n} {\tilde{I}}_{sn , HR} / {\tilde{I}}_{as} \vert & ( Fault in Phase A ) \\ \vert - 3 {Z}_{n} {\tilde{I}}_{sn , HR} / {a}^{2} {\tilde{I}}_{bs} \vert & ( Fault in Phase B ) \\ \vert - 3 {Z}_{n} {\tilde{I}}_{sn , HR} / a {\tilde{I}}_{cs} \vert & ( Fault in Phase C )\end{matrix} \qquad ( eq 30 )$$

From these understandings, it can be understood that the downstream Rₕᵣ estimate can be obtained with high precision during the startup transient (robust to source voltage unbalance and inherent machine or motor asymmetry) and the negative sequence current can be calculated accurately to ascertain the desired effects. The main advantage of using the negative sequence current during the startup transient compared to steady state conditions is its robustness to supply voltage unbalance and inherent system asymmetry, which changes around depending on operating conditions and is unknown.

As mentioned earlier, one aspect of embodiments of the invention is the ability to continuously monitor performance of electrical power circuitry. By functioning, while the circuitry is operative, and perhaps identifying an appropriate load change condition that occurs in normal operation, the system can facilitate substantially continuously ascertaining the existence of a potential anomaly. Whenever an item such as an electric machine or motor is turned on or off, embodiments can conduct an evaluation to see if there is a problem. Thus, it can operate in a substantially continuous fashion (even though not achieving a test when merely running regularly). Naturally, the system can be automated and can even be scheduled to cause a load change or do a determination through programming or the like. The analyzer can serve as a substantially continuous supply path anomaly analyzer or a substantially continuous load path anomaly analyzer.

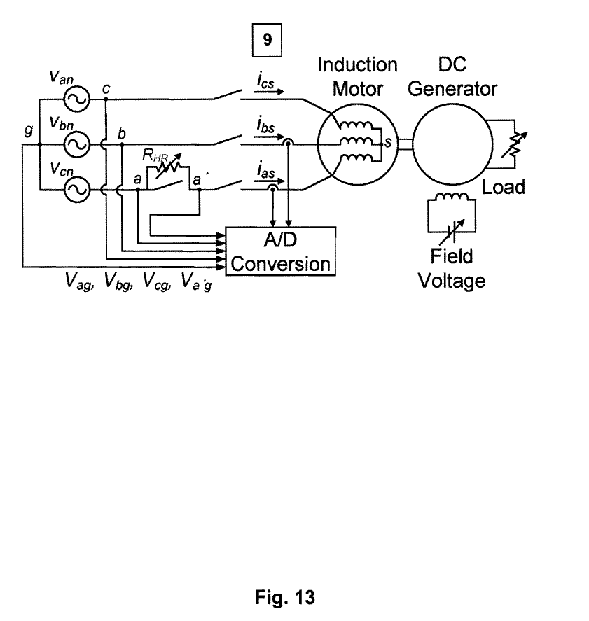

To assess the efficacy of the above techniques, a variety of experiments were conducted. These are presented as examples of the value of the methods disclosed. An experimental study was performed on a 380V, 10 hp induction machine or motor load in a laboratory environment to test the validity of the proposed upstream and downstream high-R contact monitoring techniques. The experimental test setup configuration is shown in FIG. 13. A 30 hp DC machine was coupled to the machine or motor and operated as a generator. The field voltage was controlled to adjust the power delivered to the resistor bank connected to the armature to adjust the machine or motor load level. Four line to neutral voltages, ν_{ag}, ν_{ag}, ν_{bg}, and ν_{cg}, and two line currents, iₐₛ and i_{bs}, were measured using commercial sensors and digitized with a 16 bit data acquisition system. A commercial infrared thermal camera was used to observe the temperature rise and distribution due to high-R connections. High-R connections were simulated by inserting high precision resistors with values of R_{HR}=0.0, 0.05, 0.1, 0.2, and 0.4Ω between the source and machine or motor terminals of phase A. In addition to using high precision resistors, a terminal block with the bolts intentionally corroded was also used to test high-R connections under more realistic conditions. To simulate corrosion of bolts due to salt in industrial plants located near the seashore, bolts were placed in 20% salt water for one week to accelerate the corrosion process. The corroded bolts were used in one of the three phases (phase A) on both sides of the terminal block, as shown in FIG. 2. The voltage was measured on the machine or motor and source sides of the resistor (or corroded bolt), as shown in FIG. 9, to simulate poor contacts located upstream and downstream from the point of voltage measurement. Separate tests were also conducted with a 0.56 kW (0.75 Hp) induction machine and ten different upstream resistances at 9 different voltage unbalances. The voltages and the currents were recorded simultaneously upstream and downstream of the resistance R with two Exp 3000 from Baker Instrument Company.

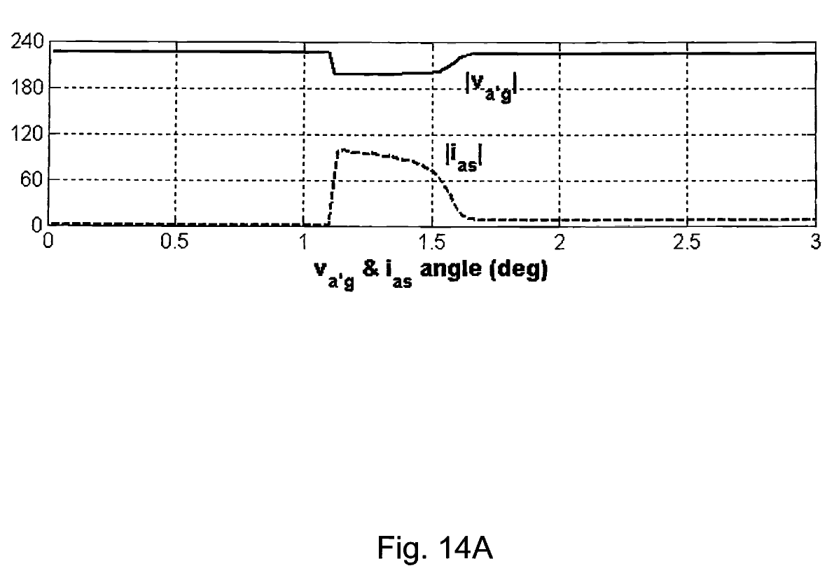

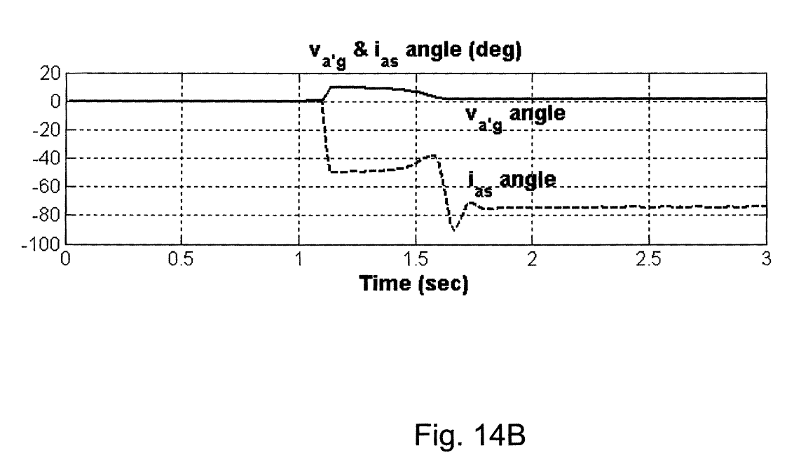

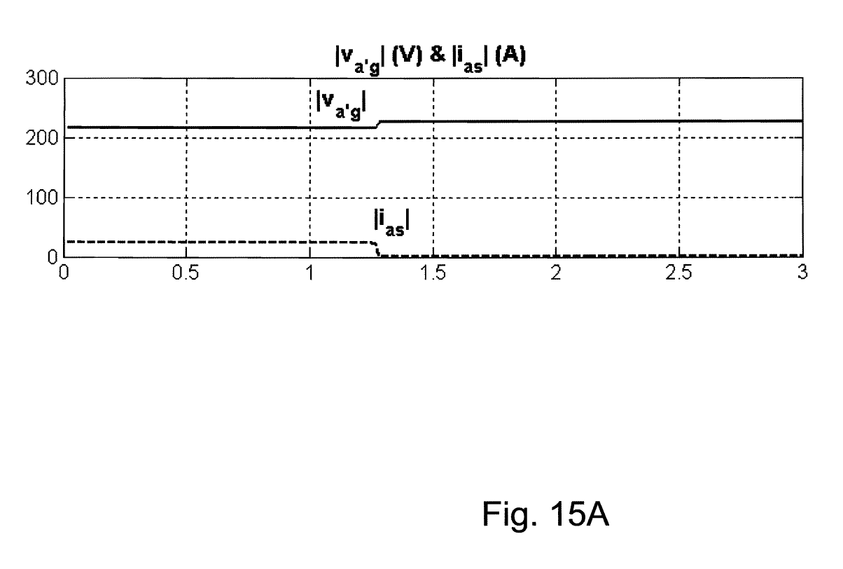

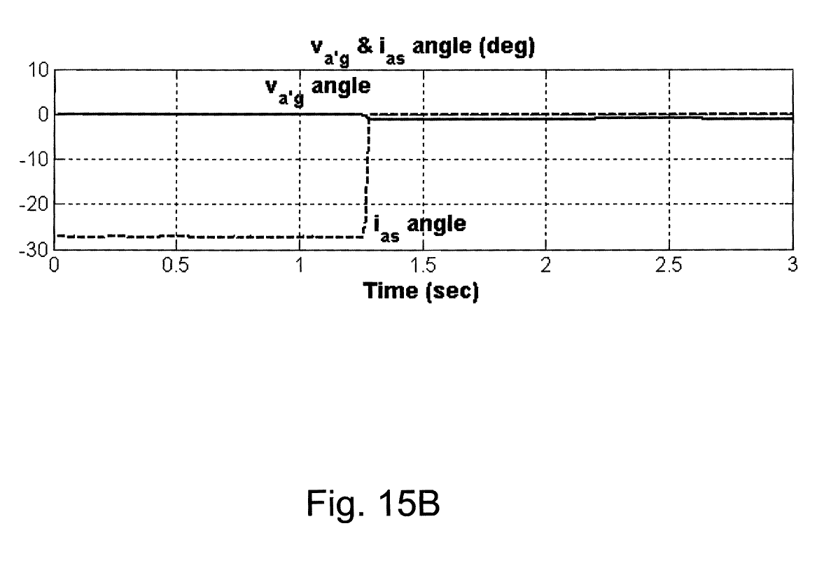

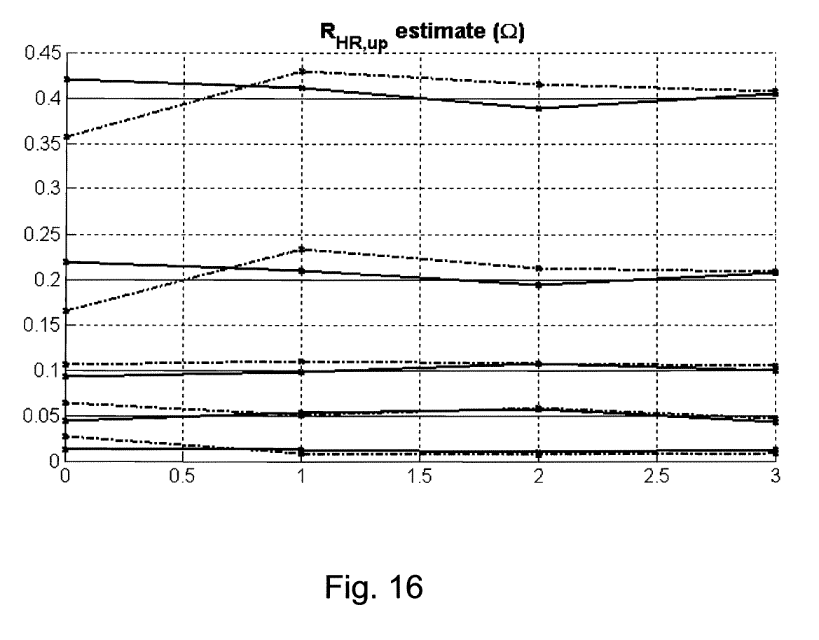

In the initial tests, the magnitude and phase angle measurements of ν_{ag} and iₐₛ when the machine or motor is line-started under no load and stopped under full load conditions with R_{HR,up}=0.4Ω, are shown in FIG. 14-15, respectively. The variation in the ν_{ag} and iₐₛ magnitude and phase angle between shutdown and startup/steady state for monitoring of upstream high-R contacts can be clearly observed in FIGS. 14-15, as predicted in FIGS. 10-11. The value of R_{HR,up} was calculated from the phase A and B measurements from (eq13) using the startup data, and from (eq14) using the steady state data when the machine or motor is operating under no load, half load, and full load conditions. The estimates of R_{HR,up} obtained under startup, full load, half load, and no load conditions for R_{HR,up}=0.0, 0.05, 0.1, 0.2, 0.4Ω are summarized in Table 18 and FIG. 16. It can be seen in the table and figure that the increase in the R_{HR,up} estimate can be clearly observed, and it is sufficiently accurate for monitoring and protection purposes. It can also be seen that the overall trend is that the accuracy of the R_{HR,up} estimate improves for higher load current since the voltage drop across R_{HR,up} (delta V) increases. The load current under no load half load, full load, and startup condition were 7.0 A, 9.8 A, 16.8 A, and 97.0 A, respectively.

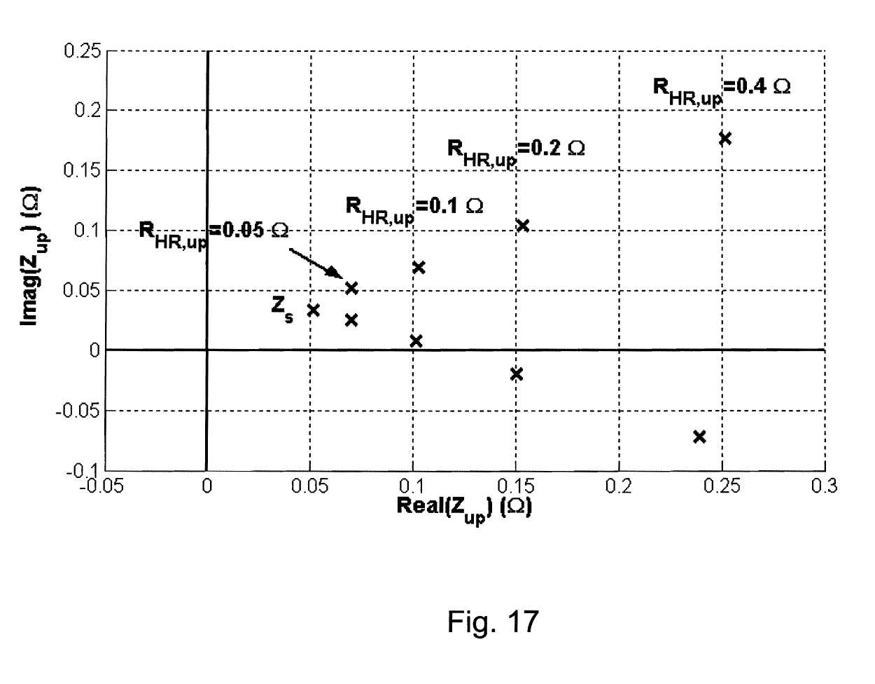

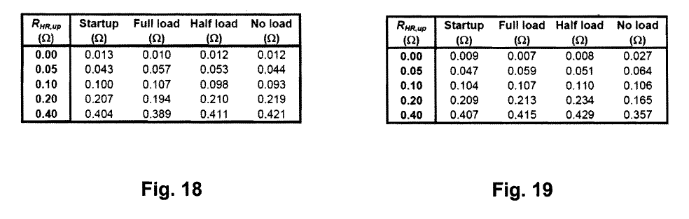

The method proposed for estimating R_{HR,up} from the line to line voltage measurements was also tested under no load startup, and full load, half load, and no load shut down conditions for R_{HR,up}=0.0, 0.05, 0.1, 0.2, 0.4 Ω. When the high precision resistors were placed upstream in phase A, the upstream impedance calculated under startup from the line voltages and currents using (eq10), are shown in a complex plane in FIG. 17. It can be seen that the pattern of the three phase upstream impedances is identical to the pattern predicted in FIG. 12. The AB and CA phase upstream impedances are located to the right hand side of Zₛ (phase BC upstream impedance) and separated by approximately 60 degrees, and the distance from Zₛ is proportional to R_{HR,up}. The estimates of R_{HR,up} calculated from (eq11) under all the test conditions for R_{HR,up}=0.0, 0.05, 0.1, 0.2, 0.4 Ω, are summarized in Table 19 and FIG. 16. It can be seen in the table and figure that R_{HR,up} can be estimated with sufficient accuracy for protection purposes, and the accuracy of the estimate improves with load current level.

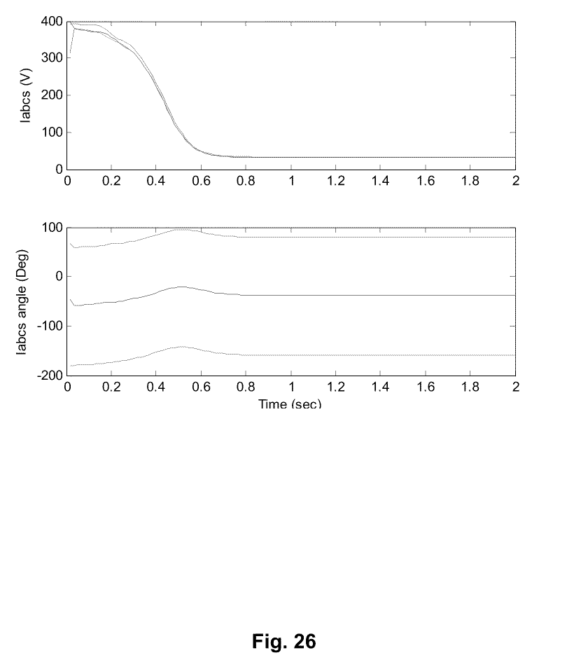

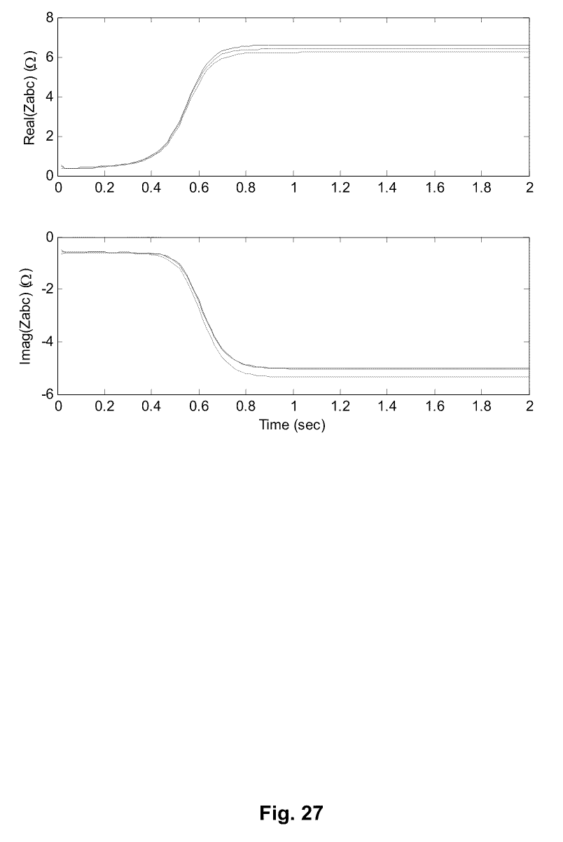

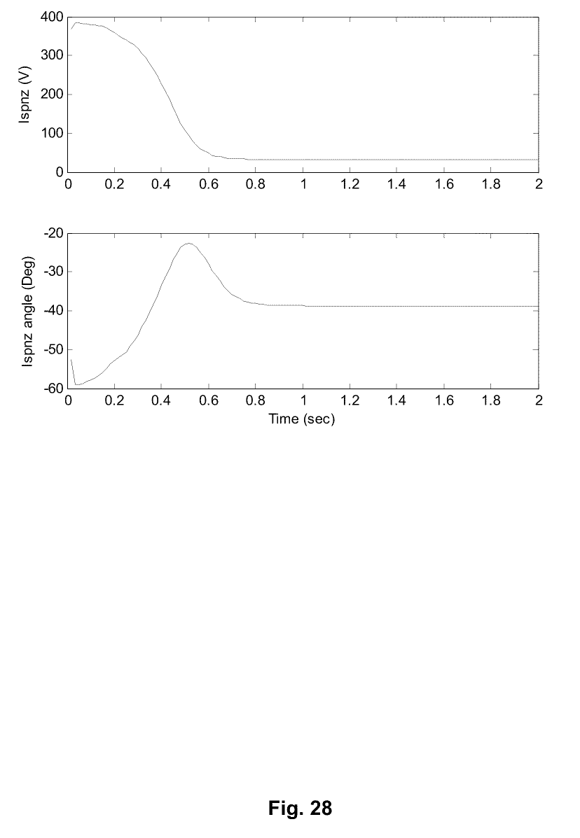

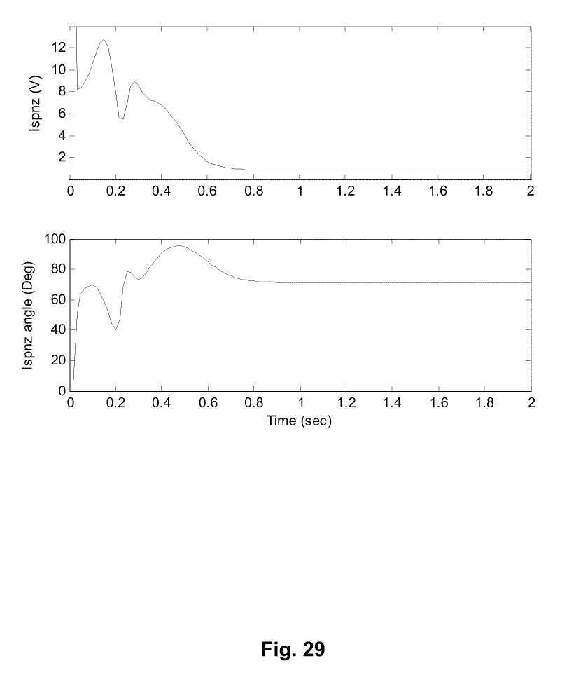

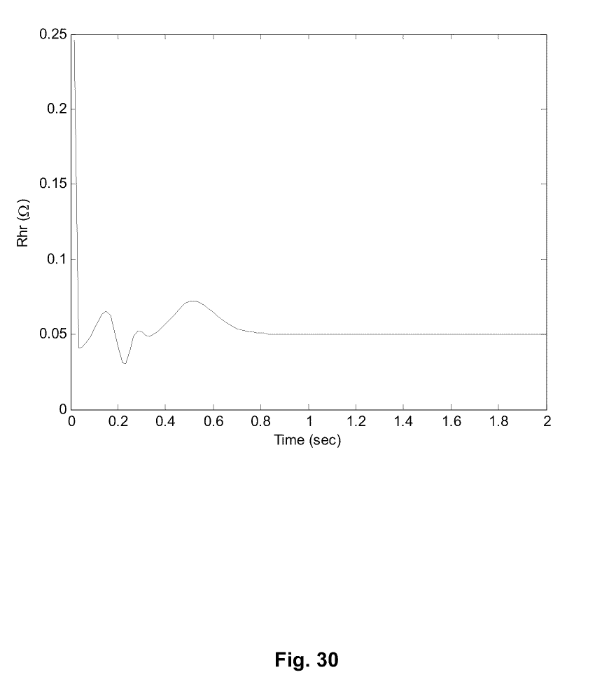

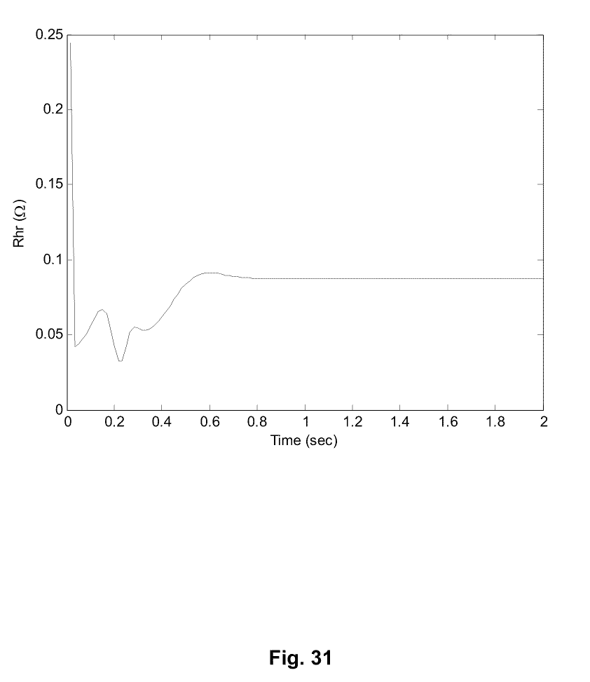

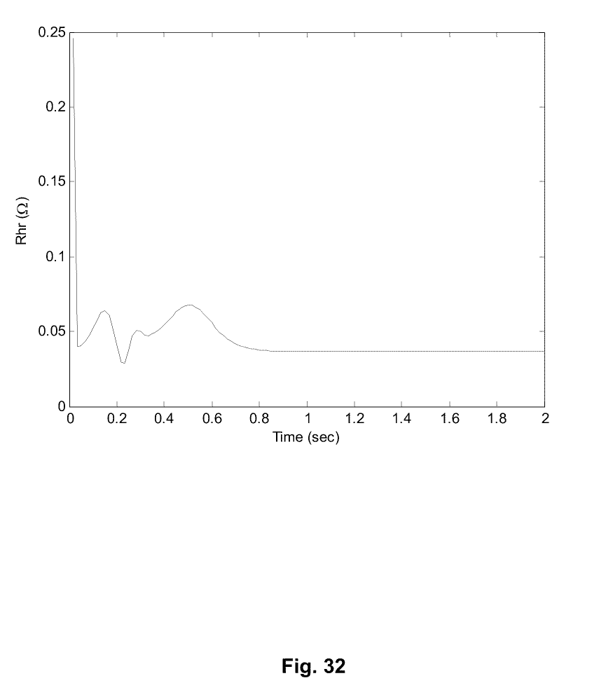

Simulation of a 50 hp machine or motor with high resistance contact in phase A of 50 mΩ is shown in FIGS. 26-31. The magnitude and phase angle of the three phase currents, impedance, and negative sequence current are shown in FIGS. 26-28, respectively. The contact resistance estimate under ideal conditions, 0.5% unbalance in the phase A voltage, and 0.5% inherent negative sequence current are shown in FIGS. 29-31, respectively. It can be seen that the steady state estimate is significantly influenced, but the transient estimate is not as influenced by supply voltage unbalance and inherent motor asymmetry.

Using the initial test setup, the downstream high-R contact monitoring technique was tested by changing R_{HR,down} from 0.0 to 0.4 Ω in discrete steps using a set of high-precision resistors and mechanical switches. The measured value of Zₙ was 0.912+j2.10Ω. (2.29∠66.5°Ω), and the value of I_{sn,r} estimated from (eq28) under healthy conditions was 0.114+j0.158Ω(0.195∠54.2°Ω). The magnitude and phase angle of the measured νₛₙ and iₛₙ, and i_{sn,HR} (calculated from (eq26)) are shown in FIG. 20. It can be seen in this figure that νₛₙ is independent of change in R_{HR}, and iₛₙ changes with R_{HR}, as expected. It can also be seen that i_{sn,HR}, which is the compensated iₛₙ, increases with fault severity, and can be used for determining the existence of downstream high-R contacts. The location of the fault can be determined as phase A, since the angle of i_{sn,HR} is approximately 180°-27.0° (angle of iₐₛ)—66.5° (angle of Zₙ), as shown in (eq29). The severity of the fault (value of R_{HR}) can be determined from (eq30) based on the fault location information. The R_{HR,down} estimates are shown in FIG. 21, when R_{HR,down} was increased from 0 to 0.4Ω. It can be seen in FIG. 15 that R_{HR,down} can be estimated with high precision using the proposed technique.

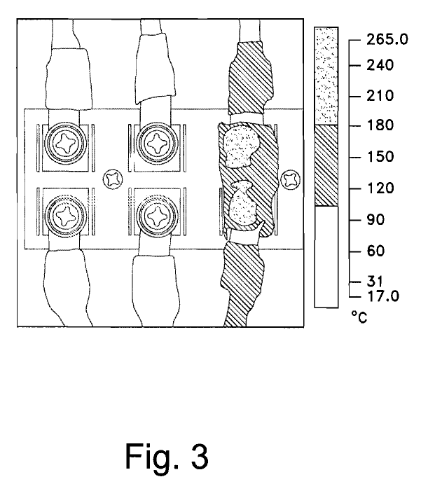

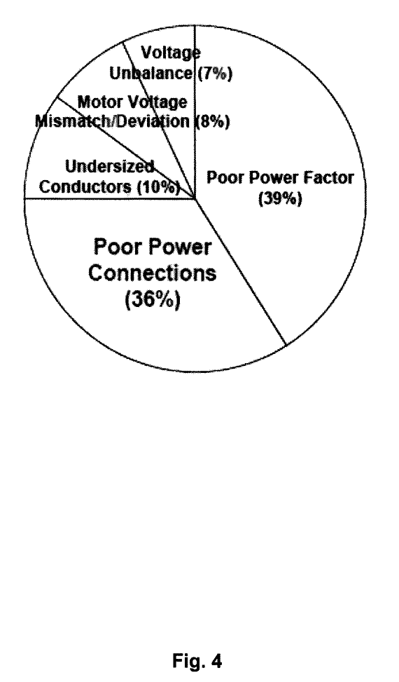

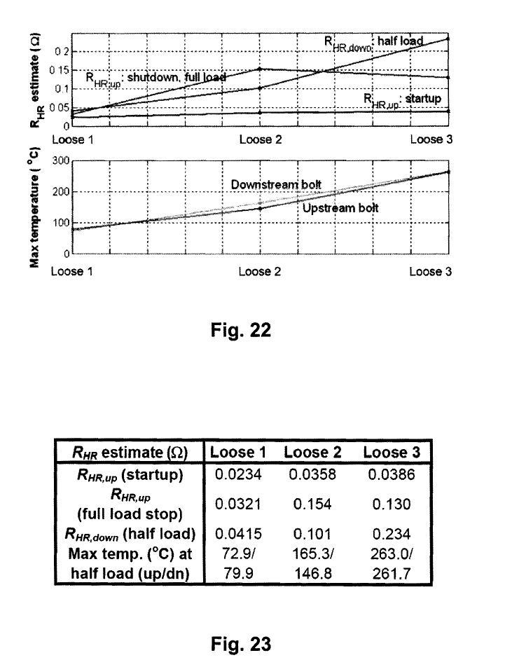

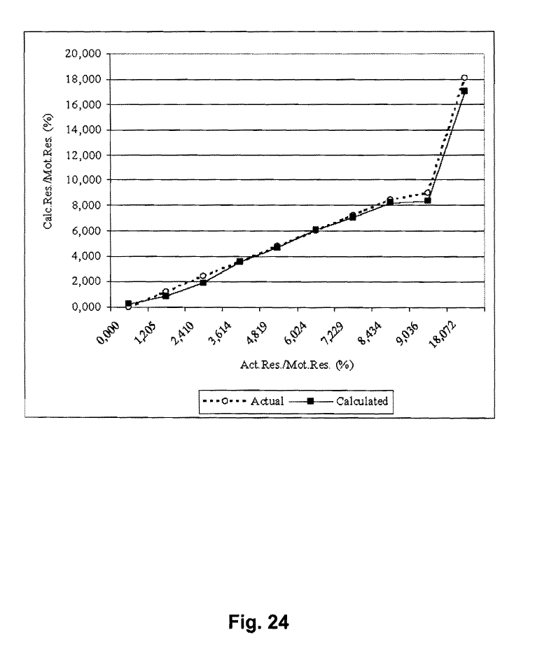

To test the proposed techniques under more realistic high-R fault conditions, the resistors in FIG. 13 were replaced with a terminal block, where both sides were connected with corroded bolts, as shown in FIG. 3. When the corroded bolts were tightened with appropriate torque, an increase in the R_{HR} estimate or temperature could not be observed. An increase in the contact resistance and temperature was observed when corroded bolts were loosened. The bolts on both the upstream and downstream sides of the terminal block were intentionally loosened in three discrete steps to increase the contact resistance. The three loosened conditions are referred to as “loose 1”, “loose 2”, and “loose 3” conditions in Table 23 and FIG. 22. The R_{HR,up} estimates were obtained under machine or motor startup at no load and machine or motor shutdown under full load conditions. The R_{HR,down} estimates were obtained in steady state under half load conditions after the contact temperature reached thermal equilibrium. The R_{HR} estimates and the maximum upstream and downstream contact temperature measured with the infrared camera under 50% rated load under each test condition, are summarized in Table 23 and FIG. 22.

It can be clearly observed in the table and figure that the contact resistance and temperature increase as the connection is loosened. It can also be seen that the estimate of R_{HR} is different depending on under what condition it has been estimated. Considering that the R_{HR} estimates are reasonably accurate and consistent (independent of when it is estimated) when using resistors (Tables 18-19 and FIGS. 16 and 21), it can be concluded that the contact resistance changes depending on the operating condition. The value of the R_{HR} estimate is low under startup condition when the current is high (97.0 A) and high under half load condition when the current is the low (9.8 A), except for one data point. Although further investigation is required on the dependency of current and contact resistance, the results indicate that the contact resistance decreases as the current flow through the contact increases. It can also be seen that the dependency of the R_{HR} estimates on current is more significant when the contacts are loose. The variation in the R_{HR} estimates is relatively small under the “loose 1” condition compared to the “loose 2” or “loose 3” conditions. The value of the R_{HR} estimates were inconsistent at times when the contact was unstable, which made testing under identical conditions very difficult. The inconsistency in the “shut down at full load” in the “loose 2” condition of Table III and FIG. 16 can be attributed to inconsistent contact resistance (The same test could not be repeated since the identical high-R contact condition could not

The temperature increased up to over 260° C. at half load under the “loose 3” condition, and intermittent arcing was observed at the corroded high-R contact when loosened. It has been observed during the course of the experimental testing that high-R connections are very dangerous due to localized heating and arcing. The results in FIGS. 10-16 and Tables 18, 19, and 23 show that the existence, location, and severity of high-R connections located upstream and downstream in the industrial distribution system can be reliably detected from the stator voltage and current measurements using the proposed technique.

As the above examples show, the inventive techniques for monitoring the existence, location, and severity of high-R connections located upstream and downstream in the electrical distribution circuit yield good results. They can be implemented based on the existing voltage and current measurements, and are capable of providing fully automated monitoring of poor contact problems. Upstream contact problems are monitored whenever the load is started or shutdown based on the voltage and current variation, and downstream contact problems are monitored on-line under steady state operation based on the negative sequence current. The experimental studies verify that high resistance electrical connections can be reliably detected. These techniques are convenient compared to existing off-line or walk-around type tests (infrared or voltage drop) since they provide automated monitoring of upstream and downstream contact quality without additional hardware requirements. With these methods, the maintenance costs and safety risks can also be reduced, since conventional walk-around tests can be performed when the monitoring system alarms the user of high- R contact problems. Embodiments can help improve the reliability, efficiency, and safety of the industrial facility.

As can be easily understood from the foregoing, the basic concepts of the present invention may be embodied in a variety of ways. It involves both test techniques as well as devices to accomplish the appropriate testing. In this application, the various techniques are disclosed as part of the results shown to be achieved by the various devices described and as steps which are inherent to utilization. They are simply the natural result of utilizing the devices as intended and described. In addition, while some devices are disclosed, it should be understood that these not only accomplish certain methods but also can be varied in a number of ways. Importantly, as to all of the foregoing, all of these facets should be understood to be encompassed by this disclosure.

The reader should be aware that the specific discussion may not explicitly describe all embodiments possible; many alternatives are implicit. It also may not fully explain the generic nature of the invention and may not explicitly show how each feature or element can actually be representative of a broader function or of a great variety of alternative or equivalent elements. Again, these are implicitly included in this disclosure. Where the invention is described in device-oriented terminology, each element of the device implicitly performs a function. Apparatus claims may not only be included for the device described, but also method or process claims may be included to address the functions the invention and each element performs. Neither the description nor the terminology is intended to limit the scope of the claims that will be included in any subsequent patent application.

It should also be understood that a variety of changes may be made without departing from the essence of the invention. Such changes are also implicitly included in the description. They still fall within the scope of this invention. A broad disclosure encompassing both the explicit embodiment(s) shown, the great variety of implicit alternative embodiments, and the broad methods or processes and the like are encompassed by this disclosure. With this understanding, the reader should be aware that this disclosure is to be understood to support any subsequently filed patent application that may seek examination of as broad a base of claims as deemed within the applicant's right and may be designed to yield a patent covering numerous aspects of the invention both independently and as an overall system.

Further, each of the various elements of the invention and claims may also be achieved in a variety of manners. Additionally, when used or implied, an element is to be understood as encompassing individual as well as plural structures that may or may not be physically connected. This disclosure should be understood to encompass each such variation, be it a variation of an embodiment of any apparatus embodiment, a method or process embodiment, or even merely a variation of any element of these. Particularly, it should be understood that as the disclosure relates to elements of the invention, the words for each element may be expressed by equivalent apparatus terms or method terms—even if only the function or result is the same. Such equivalent, broader, or even more generic terms should be considered to be encompassed in the description of each element or action. Such terms can be substituted where desired to make explicit the implicitly broad coverage to which this invention is entitled. As but one example, it should be understood that all actions may be expressed as a means for taking that action or as an element which causes that action. Similarly, each physical element disclosed should be understood to encompass a disclosure of the action which that physical element facilitates. Regarding this last aspect, as but one example, the disclosure of a “sensor” should be understood to encompass disclosure of the act of “sensing”—whether explicitly discussed or not—and, conversely, were there effectively disclosure of the act of “sensing”, such a disclosure should be understood to encompass disclosure of a “sensor” and even a “means for sensing” Such changes and alternative terms are to be understood to be explicitly included in the description.

Any patents, publications, or other references mentioned in this application for patent are hereby incorporated by reference. Any priority case(s) claimed by this application is hereby appended and hereby incorporated by reference. In addition, as to each term used it should be understood that unless its utilization in this application is inconsistent with a broadly supporting interpretation, common dictionary definitions should be understood as incorporated for each term and all definitions, alternative terms, and synonyms such as contained in the Random House Webster's Unabridged Dictionary, second edition are hereby incorporated by reference. Finally, all references listed in the list of References To Be Incorporated By Reference In Accordance With The Provisional Patent Application or other information statement filed with the application are hereby appended and hereby incorporated by reference, however, as to each of the above, to the extent that such information or statements incorporated by reference might be considered inconsistent with the patenting of this/these invention(s) such statements are expressly not to be considered as made by the applicant(s).

Thus, the applicant(s) should be understood to have support to claim and make a statement of invention to at least: i) each of the test devices as herein disclosed and described, ii) the related methods disclosed and described, iii) similar, equivalent, and even implicit variations of each of these devices and methods, iv) those alternative designs which accomplish each of the functions shown as are disclosed and described, v) those alternative designs and methods which accomplish each of the functions shown as are implicit to accomplish that which is disclosed and described, vi) each feature, component, and step shown as separate and independent inventions, vii) the applications enhanced by the various systems or components disclosed, viii) the resulting products produced by such systems or components, ix) each system, method, and element shown or described as now applied to any specific field or devices mentioned, x) methods and apparatuses substantially as described hereinbefore and with reference to any of the accompanying examples, xi) the various combinations and permutations of each of the elements disclosed, xii) each potentially dependent claim or concept as a dependency on each and every one of the independent claims or concepts presented, and xiii) all inventions described herein. In addition and as to computer aspects and each aspect amenable to programming or other electronic automation, the applicant(s) should be understood to have support to claim and make a statement of invention to at least: xvi) processes performed with the aid of or on a computer as described throughout the above discussion, xv) a programmable apparatus as described throughout the above discussion, xvi) a computer readable memory encoded with data to direct a computer comprising means or elements which function as described throughout the above discussion, xvii) a computer configured as herein disclosed and described, xviii) individual or combined subroutines and programs as herein disclosed and described, xix) the related methods disclosed and described, xx) similar, equivalent, and even implicit variations of each of these systems and methods, xxi) those alternative designs which accomplish each of the functions shown as are disclosed and described, xxii) those alternative designs and methods which accomplish each of the functions shown as are implicit to accomplish that which is disclosed and described, xxiii) each feature, component, and step shown as separate and independent inventions, and xxiv) the various combinations and permutations of each of the above.

With regard to claims whether now or later presented for examination, it should be understood that for practical reasons and so as to avoid great expansion of the examination burden, the applicant may at any time present only initial claims or perhaps only initial claims with only initial dependencies. The office and any third persons interested in potential scope of this or subsequent applications should understand that broader claims may be presented at a later date in this case, in a case claiming the benefit of this case, or in any continuation in spite of any preliminary amendments, other amendments, claim language, or arguments presented, thus throughout the pendency of any case there is no intention to disclaim or surrender any potential subject matter. It should be understood that if or when broader claims are presented, such may require that any relevant prior art that may have been considered at any prior time may need to be re-visited since it is possible that to the extent any amendments, claim language, or arguments presented in this or any subsequent application are considered as made to avoid such prior art, such reasons may be eliminated by later presented claims or the like. Both the examiner and any person otherwise interested in existing or later potential coverage, or considering if there has at any time been any possibility of an indication of disclaimer or surrender of potential coverage, should be aware that no such surrender or disclaimer is ever intended or ever exists in this or any subsequent application. Limitations such as arose in Hakim v. Cannon Avent Group, PLC, 479 F.3d 1313 (Fed. Cir 2007), or the like are expressly not intended in this or any subsequent related matter. In addition, support should be understood to exist to the degree required under new matter laws—including but not limited to European Patent Convention Article 123(2) and United States Patent Law 35 USC 132 or other such laws—to permit the addition of any of the various dependencies or other elements presented under one independent claim or concept as dependencies or elements under any other independent claim or concept. In drafting any claims at any time whether in this application or in any subsequent application, it should also be understood that the applicant has intended to capture as full and broad a scope of coverage as legally available. To the extent that insubstantial substitutes are made, to the extent that the applicant did not in fact draft any claim so as to literally encompass any particular embodiment, and to the extent otherwise applicable, the applicant should not be understood to have in any way intended to or actually relinquished such coverage as the applicant simply may not have been able to anticipate all eventualities; one skilled in the art, should not be reasonably expected to have drafted a claim that would have literally encompassed such alternative embodiments.

Further, if or when used, the use of the transitional phrase “comprising” is used to maintain the “open-end” claims herein, according to traditional claim interpretation. Thus, unless the context requires otherwise, it should be understood that the term “comprise” or variations such as “comprises” or “comprising”, are intended to imply the inclusion of a stated element or step or group of elements or steps but not the exclusion of any other element or step or group of elements or steps. Such terms should be interpreted in their most expansive form so as to afford the applicant the broadest coverage legally permissible. The use of the phrase, “or any other claim” is used to provide support for any claim to be dependent on any other claim, such as another dependent claim, another independent claim, a previously listed claim, a subsequently listed claim, and the like. As one clarifying example, if a claim were dependent “on claim 20 or any other claim” or the like, it could be re-drafted as dependent on claim 1, claim 15, or even claim 715 (if such were to exist) if desired and still fall with the disclosure. It should be understood that this phrase also provides support for any combination of elements in the claims and even incorporates any desired proper antecedent basis for certain claim combinations such as with combinations of method, apparatus, process, and the like claims.

Finally, any claims set forth at any time are hereby incorporated by reference as part of this description of the invention, and the applicant expressly reserves the right to use all of or a portion of such incorporated content of such claims as additional description to support any of or all of the claims or any element or component thereof, and the applicant further expressly reserves the right to move any portion of or all of the incorporated content of such claims or any element or component thereof from the description into the claims or vice-versa as necessary to define the matter for which protection is sought by this application or by any subsequent continuation, division, or continuation-in-part application thereof, or to obtain any benefit of, reduction in fees pursuant to, or to comply with the patent laws, rules, or regulations of any country or treaty, and such content incorporated by reference shall survive during the entire pendency of this application including any subsequent continuation, division, or continuation-in-part application thereof or any reissue or extension thereon.

1. A method of quantifying electric machine circuitry anomalies comprising the steps of:
accessing at least a portion of an electric machine power circuit characterizeable as having a supply path and a load path;
load change condition sensing at least one electrical effect at a sense location between said supply path and said load path;
measuring a supply path voltage effect at said sense location; and
ascertaining the existence of a supply path anomaly condition from said step of measuring a supply path voltage effect at said sense location.

2. A method of quantifying electric machine circuitry anomalies comprising the steps of:
accessing at least a portion of an electric machine power circuit characterizeable as having a supply path and a load path;
sensing at least one electrical effect at a sense location between said supply path and said load path;
measuring a supply path voltage effect at said sense location;
measuring a supply path current effect at said sense location;
quantitatively ascertaining the existence of a supply path anomaly condition from said steps of measuring a supply path voltage effect and measuring a supply path current effect at said sense location.

3. A method of quantifying electric machine circuitry anomalies as described in claim 2 or 3 wherein said step of sensing at least one electrical effect comprises the step of sensing said at least one electrical effect at only said sense location.

4. A method of quantifying electric machine circuitry anomalies as described in 2 wherein said step of sensing at least one electrical effect comprises the step of load change condition sensing at least one electrical effect.

5-6. (canceled)

7. A method of quantifying electric machine circuitry anomalies as described in 2 wherein said step of sensing at least one electrical effect comprises the step of operationally active circuitry sensing at least one electrical effect while said machine circuitry is in an operative configuration.

8-11. (canceled)

12. A method of quantifying electric machine circuitry anomalies as described in claim 1 or 2 wherein said step of quantitatively ascertaining the existence of a supply path anomaly condition comprises the step of ascertaining an electrical magnitude variation.

13. A method of quantifying electric machine circuitry anomalies as described in claim 2 wherein said steps of quantitatively ascertaining the existence of a supply path anomaly condition comprises the step of ascertaining an electrical angle variation.

14. A method of quantifying electric machine circuitry anomalies as described in claim 1 or 2 wherein said step of quantitatively ascertaining the existence of a supply path anomaly condition comprises the step of utilizing historical data for said electric machine circuitry.

15-20. (canceled)

21. A method of quantifying electric machine circuitry anomalies as described in claim 2 wherein said step of quantitatively ascertaining the existence of a supply path anomaly condition comprises the step of sensing an asymmetry condition for said electrical machine circuitry.

22-25. (canceled)

26. A method of quantifying electric machine circuitry anomalies as described in claim 2 wherein said step of quantitatively ascertaining the existence of a supply path anomaly condition comprises the step of conducting a low resistance phase comparison for said electric machine circuitry.

27-29. (canceled)

30. A method of testing electric machine circuitry comprising the steps of:
accessing at least a portion of an electric machine power circuit characterizeable as having a supply path and a load path;
experiencing a load change condition within said load path;
load change condition sensing at least one electrical effect from said load change condition at a sense location between said supply path and said load path;
determining at least one electrical parameter at said sense location; and
ascertaining if a supply path anomaly condition exists from said step of determining at least one electrical parameter at said sense location.

31. A method of testing electric machine circuitry as described in claim 30 wherein said step of load change condition sensing at least one electrical effect comprises the step of load change condition sensing said at least one electrical effect at only said sense location.

32. A method of testing electric machine circuitry as described in claim 31 wherein said step of load change condition sensing at least one electrical effect comprises the step of operationally active circuitry load change condition sensing at least one electrical effect while said machine circuitry is in an operative configuration.

33. A method of testing electric machine circuitry as described in claim 30 and further comprising the step of assuring a load path steady state operational condition while accomplishing said step of load change condition sensing.

34. A method of testing electric machine circuitry as described in claim 31 wherein said step of experiencing a load change condition comprises the step of switching an operational condition load change condition.

35. A method of testing electric machine circuitry as described in claim 30 wherein said step of experiencing a load change condition comprises the step of experiencing a substantial load change condition.

36. A method of testing electric machine circuitry as described in claim 35 wherein said step of experiencing a substantial load change condition is selected from a group consisting of:
experiencing a greater than rated current load change condition; and
experiencing a greater than four times rated current load change condition.

37. A method of testing electric machine circuitry as described in claim 30 wherein said step of experiencing a load change condition comprises the step of experiencing a normative operational load change condition.

38. (canceled)

39. A method of testing electric machine circuitry as described in claim 37 wherein said step of experiencing a normative operational load change condition comprises a step selected from a group consisting of:
experiencing a machine start up condition;
experiencing a machine shut down condition; and
experiencing a machine power factor change condition.

40-44. (canceled)

45. A method of testing electric machine circuitry as described in claim 30 or wherein said step of ascertaining if a supply path anomaly condition exists comprises the step of conducting a pre- and post-load change condition comparison.

46-48. (canceled)

49. A method of testing electric machine circuitry as described in claim 45 wherein said step of conducting a pre- and post-load change condition comparison is selected from a group consisting of:
conducting a pre- and post-load change condition voltage effect comparison;
conducting a pre- and post-load change condition current effect comparison;
conducting a pre- and post-load change condition magnitude effect comparison;
conducting a pre- and post-load change condition angle effect comparison;
conducting a pre- and post-load change condition voltage magnitude effect comparison;
conducting a pre- and post-load change condition voltage angle effect comparison;
conducting a pre- and post-load change condition current magnitude effect comparison;
conducting a pre- and post-load change condition current angle effect comparison; and
conducting a pre- and post-load change condition comparison that is any combination or permutation of the above.

50. A method of identifying an incipient fault electric machine circuitry anomaly comprising the steps of:
accessing at least a portion of an electric machine power circuit characterizeable as having a supply path and a load path;
sensing at least one electrical effect at a sense location between said supply path and said load path;
determining at least one electrical parameter at said sense location; and
ascertaining if an incipient fault supply path anomaly condition exists from said step of determining at least one electrical parameter at said sense location.

51. A method of identifying an incipient fault electric machine circuitry anomaly as described in claim 50 wherein said step of sensing at least one electrical effect comprises the step of sensing said at least one electrical effect at only said sense location.

52. (canceled)

53. A method of identifying an incipient fault electric machine circuitry anomaly as described in claim 50 wherein said step of sensing at least one electrical effect comprises the step of operationally active circuitry sensing at least one electrical effect while said machine circuitry is in an operative configuration.

54. A method of identifying an incipient fault electric machine circuitry anomaly as described in claim 53 wherein said step of sensing at least one electrical effect comprises the step of load change condition sensing at least one electrical effect.

55-56. (canceled)

57. A method of identifying an incipient fault electric machine circuitry anomaly as described in claim 53 wherein said step of ascertaining if an incipient fault supply path anomaly condition exists comprises the step of interphase comparing electrical machine circuitry effects.

58-59. (canceled)

60. A method of identifying an incipient fault electric machine circuitry anomaly as described in claim 57 wherein said step of ascertaining if an incipient fault supply path anomaly condition exists comprises the step of conducting a low resistance phase comparison for said electric machine circuitry.

61. (canceled)

62. A method of identifying an incipient fault electric machine circuitry anomaly as described in claim 53 wherein said step of ascertaining if an incipient fault supply path anomaly condition exists comprises the step of substantially continuously ascertaining if an incipient fault supply path anomaly condition exists during operating conditions for said electric machine circuitry.

63-105. (canceled)

106. A method of evaluating electric machine circuitry as described in claim 2, 30, or 50 wherein said step of ascertaining comprises the step of estimating an individual phase condition within said electric machine circuitry.

107. A method of evaluating electric machine circuitry as described in claim 106 wherein said step of estimating an individual phase condition within said electric machine circuitry comprises the step of estimating a supply path power circuitry condition within said electric machine circuitry.

108. A method of evaluating electric machine circuitry as described in claim 107 wherein said step of estimating a supply path power circuitry condition within said electric machine circuitry comprises the step of estimating a purely resistive supply path anomaly.

109. A method of evaluating electric machine circuitry as described in claim 107 wherein said step of estimating a supply path power circuitry condition comprises the steps of:
measuring a supply path voltage variation; and
measuring a supply path current variation.

110. A method of evaluating electric machine circuitry as described in claim 106 wherein said step of estimating an individual phase condition within said electric machine circuitry comprises the step of estimating a load path power circuitry condition within said electric machine circuitry.

111. A method of evaluating electric machine circuitry as described in claim 110 wherein said step of estimating a load path power circuitry condition within said electric machine circuitry comprises the step of estimating a purely resistive load path anomaly.

112. A method of evaluating electric machine circuitry as described in claim 2, 30, or 50 and further comprising the step of ascertaining if a load path anomaly condition exists from said step of determining at least one electrical parameter at said sense location.

113. A method of evaluating electric machine circuitry as described in claim 112 and further comprising the step of experiencing a load change condition within said load path, and wherein said step of sensing comprises the step of load change condition sensing at least one electrical effect.

114. A method of evaluating electric machine circuitry as described in claim 112 wherein said step of ascertaining if a load path anomaly condition exists comprises the step of sensing at least one load path electrical effect at said sense location between said supply path and said load path.

115. (canceled)

116. A method of evaluating electric machine circuitry as described in claim 114 wherein said step of sensing at least one load path electrical effect comprises the step of sensing a load path current angle effect.

117. A method of evaluating electric machine circuitry as described in claim 116 wherein said step of sensing a load path current angle effect comprises the step of sensing a negative sequence current.

118-120. (canceled)

121. A method of evaluating electric machine circuitry as described in claim 113 wherein said step of ascertaining comprises the step of conducting a pre- and post-load change condition comparison.

122-244. (canceled)
